(19) United States
(12) Patent Application Publication
(10) Pub. No.: US 2026/0194404 A1
(43) Pub. Date: Jul. 9, 2026

(54) ELECTRONIC DEVICE AND METHOD OF MANUFACTURING THE SAME

(71) Applicant: Samsung Display Co., Ltd., Yongin-si (KR)

(72) Inventors: Junsu Park, Yongin-si (KR); Junhyeong Park, Yongin-si (KR); Seungjun Lee, Yongin-si (KR)

(21) Appl. No.: 19/395,494

(22) Filed: Nov. 20, 2025

(30) Foreign Application Priority Data
Jan. 6, 2025 (KR) 10-2025-0001810

(51) Int. Cl. H05K 1/14; G01L 1/14; G01L 1/20

(52) U.S. Cl. CPC G01L 1/14; G01L 1/20; H05K 1/142; H05K 2201/10128; H05K 2201/10151

(57) ABSTRACT

An electronic device including a display area and a non-display area, the electronic device includes a display device and a strain sensor attached to the display device, the strain sensor includes a sensor line portion in the display area and including a plurality of first sensor lines extending in a first direction and a plurality of second sensor lines extending in a second direction crossing the first direction, a circuit board portion including a first circuit board and a second circuit board in the non-display area, the first and circuit boards being spaced from each other, a connection line portion the non-display area, and including a plurality of first connection lines electrically connecting the plurality of first sensor lines respectively to the first circuit board, and a plurality of second connection lines electrically connecting the plurality of second sensor lines respectively to the second circuit board.

### CROSS-REFERENCE TO RELATED APPLICATION

This application claims priority to and the benefit of Korean Patent Application No. 10-2025-0001810, filed on Jan. 6, 2025, in the Korean Intellectual Property Office, the entire disclosure of which is incorporated by reference herein.

### BACKGROUND

### 1. Field

One or more embodiments of the disclosure relate to a display device, for example, a flexible display device.

### 2. Description of the Related Art

According to the development of display devices for visually displaying electrical signals, various display devices having excellent characteristics such as reduced thickness, reduced weight, and low power consumption, have been introduced. For example, flexible display devices that can be folded or rolled into a roll shape have been introduced. Recently, research and development on display devices having various structures, such as stretchable display devices that can be changed into various shapes, have been actively conducted.

### SUMMARY

One or more embodiments of the disclosure provide a display device, for example, a flexible display device.

One or more embodiments of the disclosure provide an electronic device including a display area and a non-display area, the electronic device includes a display device and a strain sensor attached to the display device, the strain sensor includes a sensor line portion in the display area and including a plurality of first sensor lines extending in a first direction and a plurality of second sensor lines extending in a second direction crossing the first direction, a circuit board portion including a first circuit board and a second circuit board in the non-display area, the first circuit board and the second circuit board being spaced from each other, a connection line portion the non-display area, and including a plurality of first connection lines electrically connecting the plurality of first sensor lines respectively to the first circuit board, and a plurality of second connection lines electrically connecting the plurality of second sensor lines respectively to the second circuit board, and a first support layer supporting the sensor line portion, the connection line portion, and the circuit board portion and having a first support surface and a second support surface opposite to the first support surface, the first circuit board is on the first support surface, and the second circuit board is on the second support surface.

In one or more embodiments, each of the plurality of first connection lines may be on the first support surface, and each of the plurality of second connection lines may be on the second support surface.

In one or more embodiments, each of the plurality of first sensor lines and the plurality of second sensor lines may have a straight-line shape, and each of the plurality of first connection lines and the plurality of second connection lines may have a serpentine shape.

In one or more embodiments, the strain sensor may further include a plurality of first connection portions electrically connecting the plurality of first connection lines respectively to the first circuit board, and a plurality of first inorganic layers respectively located between the first support layer and the plurality of first connection lines to overlap the plurality of first connection portions.

In one or more embodiments, the strain sensor may further include a plurality of first organic layers on the first support surface to respectively cover the plurality of first connection lines.

In one or more embodiments, at least two of the plurality of first connection lines may have different cross-sectional areas from one another.

In one or more embodiments, in a plan view, the first circuit board and the second circuit board may overlap each other.

In one or more embodiments, the second circuit board may include a second-1 circuit board and a second-2 circuit board, and, in a plan view, the second-1 circuit board, the first circuit board, and the second-2 circuit board may be sequentially arranged along the first direction.

In one or more embodiments, the plurality of first sensor lines and the plurality of second sensor lines may face each other.

In one or more embodiments, the first circuit board and the second circuit board may face away from each other.

In one or more embodiments, in a plan view, the plurality of first sensor lines and the plurality of second sensor lines may cross each other.

In one or more embodiments, in a cross-sectional view, the plurality of first sensor lines and the plurality of second sensor lines may be spaced from each other.

One or more embodiments of the disclosure provide a method of manufacturing an electronic device, the method includes manufacturing a strain sensor and attaching the strain sensor to a display device, the manufacturing of the strain sensor includes manufacturing a first sensor module, manufacturing a second sensor module, and bonding the first sensor module to the second sensor module, and the manufacturing of the first sensor module includes arranging a first base substrate on a first support substrate, arranging a first connection line on the first base substrate, arranging a first circuit board on the first connection line, arranging a first cover substrate on the first circuit board, removing the first support substrate and the first base substrate, and arranging a first sensor line to be in contact with the first connection line.

In one or more embodiments, in the manufacturing of the second sensor module, the second sensor module may include a second connection line, a second circuit board electrically connected to the second connection line, and a second sensor line electrically connected to the second connection line and spaced from the second circuit board.

In one or more embodiments, in the bonding of the first sensor module to the second sensor module, the first sensor line and the second sensor line may cross each other.

In one or more embodiments, in the bonding of the first sensor module to the second sensor module, the first sensor line and the second sensor line may face each other.

In one or more embodiments, in the bonding of the first sensor module to the second sensor module, the first circuit board and the second circuit board may face away from each other.

In one or more embodiments, each of the first sensor line and the second sensor line may have a straight-line shape, and each of the first connection line and the second connection line may have a serpentine shape.

In one or more embodiments, in a plan view, the first circuit board and the second circuit board may be spaced from each other.

In one or more embodiments, the second circuit board may include a second-1 circuit board and a second-2 circuit board, and, in a plan view, the second-1 circuit board, the first circuit board, and the second-2 circuit board may be sequentially arranged along the first direction.

Other aspects and features of the present disclosure other than those described above will now become apparent from the following drawings, claims, and the detailed description of the present disclosure.

According to one or more embodiments of the disclosure, a stretchable electronic device with improved durability may be provided. In particular, according to one or more embodiments of the present disclosure, an electronic device including a strain sensor with improved quality may be provided.

These effects, aspects, and features are provided as examples, and the scope of the present disclosure is not limited thereto.

### BRIEF DESCRIPTION OF DRAWINGS

FIG. 1 is a schematic perspective view of a display device according to one or more embodiments of the present disclosure.

FIGS. 2A and 2B are perspective views each illustrating a state in which the display device of FIG. 1 is stretched in a first direction.

FIG. 2C is a perspective view illustrating a state in which the display device of FIG. 1 is stretched in a second direction.

FIG. 2D is a perspective view illustrating a state in which the display device of FIG. 1 is stretched in the first direction and the second direction.

FIG. 2E is a perspective view illustrating a state in which the display device of FIG. 1 is stretched in a third direction.

FIG. 3 is a schematic plan view of a display device according to one or more embodiments of the present disclosure.

FIG. 4A is an enlarged plan view of a region IV of FIG. 3 as a portion of the display device according to one or more embodiments of the present disclosure.

FIG. 4B is an enlarged plan view of the region IV of FIG. 3 as a portion of the display device according to one or more embodiments of the present disclosure.

FIG. 4C is an enlarged plan view of the region IV of FIG. 3 as a portion of the display device according to one or more embodiments of the present disclosure.

FIG. 4D is an enlarged plan view of a display area of FIG. 3 as a portion of the display device according to one or more embodiments of the present disclosure.

FIG. 5 is a schematic cross-sectional view of a first island portion and a first bridge portion, which are arranged in a display area of a display device according to one or more embodiments of the present disclosure.

FIGS. 6A-6C are equivalent circuit diagrams each illustrating a sub-pixel of a display device according to one or more embodiments of the present disclosure.

FIG. 7A is a schematic cross-sectional view of a light-emitting element of a display device according to one or more embodiments of the present disclosure.

FIG. 7B is a schematic cross-sectional view of a light-emitting element of a display device according to one or more embodiments of the present disclosure.

FIGS. 8A and 8B are schematic cross-sectional views of an electronic device according to one or more embodiments of the present disclosure.

FIGS. 9A and 9B are schematic plan views of a strain sensor according to one or more embodiments of the present disclosure.

FIGS. 10A-10C are schematic cross-sectional views of a strain sensor according to one or more embodiments of the present disclosure.

FIG. 11 is a schematic cross-sectional view of a strain sensor according to one or more embodiments of the present disclosure.

FIG. 12A is a schematic plan view of a strain sensor according to one or more embodiments of the present disclosure.

FIG. 12B is a schematic cross-sectional view of a strain sensor according to one or more embodiments of the present disclosure.

FIG. 13 is a flowchart schematically illustrating a method of manufacturing an electronic device according to one or more embodiments of the present disclosure.

FIG. 14 is a flowchart schematically illustrating a process of manufacturing a strain sensor according to one or more embodiments of the present disclosure.

FIG. 15 is a flowchart schematically illustrating a process of manufacturing a first sensor module according to one or more embodiments of the present disclosure.

FIGS. 16A-20C are schematic cross-sectional views of a strain sensor according to one or more embodiments of the present disclosure.

FIG. 21A is a schematic perspective view of an electronic device including a display device according to one or more embodiments of the present disclosure.

FIG. 21B is a schematic block diagram of an electronic device including a display device according to one or more embodiments of the present disclosure.

FIGS. 22A-22D are schematic perspective views respectively showing embodiments of an electronic device including a display device according to one or more embodiments of the present disclosure.

FIGS. 23A-23E are schematic perspective views respectively illustrating electronic devices according to one or more embodiments of the present disclosure.

### DETAILED DESCRIPTION

As the present disclosure allows for various changes and numerous embodiments, particular embodiments will be illustrated in the drawings and described in detail in the written description. Effects, aspects, and features of the present disclosure and methods of achieving the same will be apparent with reference to embodiments and drawings described below in detail. The present disclosure may, however, be embodied in many different forms and should not be construed as being limited to the embodiments set forth herein.

The present disclosure will now be described more fully with reference to the accompanying drawings, in which embodiments of the present disclosure are shown. Like reference numerals in the drawings denote like elements, and thus their description will not be repeated.

In the following embodiments, while such terms as “first,” “second,” etc., may be used to describe various elements, such elements must not be limited to the above terms.

In the following embodiments, an expression used in the singular encompasses the expression of the plural, unless it has a clearly different meaning in the context.

In the following embodiments, it is to be understood that the terms such as “including” and “having” are intended to indicate the existence of the features, or elements disclosed in the present disclosure, and are not intended to preclude the possibility that one or more other features or elements may exist or may be added.

It will be understood that when a layer, region, or element is referred to as being formed on another layer, region, or element, it can be directly or indirectly formed on the other layer, region, or element, that is, for example, intervening layers, regions, or elements may be present.

Sizes of elements in the drawings may be exaggerated or reduced for convenience of explanation. For example, because sizes and thicknesses of components in the drawings are arbitrarily illustrated for convenience of explanation, the following embodiments are not limited thereto.

The x-axis, the y-axis, and the z-axis are not limited to three axes on the orthogonal coordinates system, and may be interpreted in a broad sense including the same. For example, the x-axis, the y-axis, and the z-axis may be perpendicular to one another, or may represent different directions that are not perpendicular to one another.

When a certain embodiment may be implemented differently, a specific process order may be performed differently from the described order. For example, two consecutively described processes may be performed substantially at the same time or performed in an order opposite to the described order.

As used herein, the term “and/or” includes any and all combinations of one or more of the associated listed items. Throughout the present disclosure, the expression “at least one of a, b or c” indicates only a, only b, only c, both a and b, both a and c, both b and c, all of a, b, and c, or any variations thereof.

In the present specification, the expression “A and/or B” indicates A, B, or A and B. In addition, the expression such as “at least one of A and B” may include A, B, or A and B.

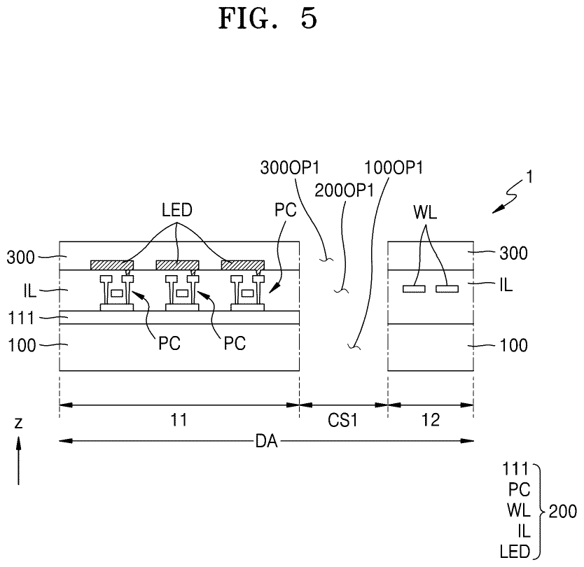

In the present disclosure, “in a plan view” means a plan view viewed in a direction perpendicular to a substrate 100 (refer to FIG. 5). That is, “A and B are spaced (e.g., spaced apart) from each other in a plan view” means “A and B are spaced (e.g., spaced apart) from each other when viewed in a direction perpendicular to the substrate 100 (refer to FIG. 5).”

In the present disclosure, “in a cross-sectional view” means a plan view cut in a direction perpendicular to the substrate 100 (refer to FIG. 5). That is, “A and B are spaced (e.g., spaced apart) from each other in a cross-sectional view” means “A and B are spaced (e.g., spaced apart) from each other in a plan view cut in a direction perpendicular to the substrate 100 (refer to FIG. 5).”

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

Hereinafter, embodiments of the present disclosure will be described with reference to the accompanying drawings.

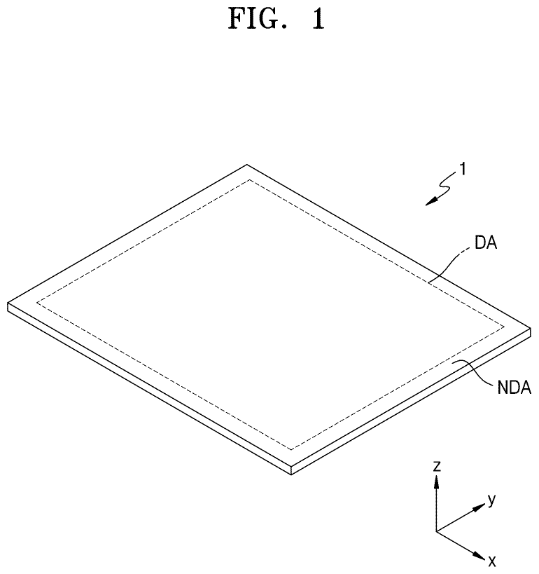

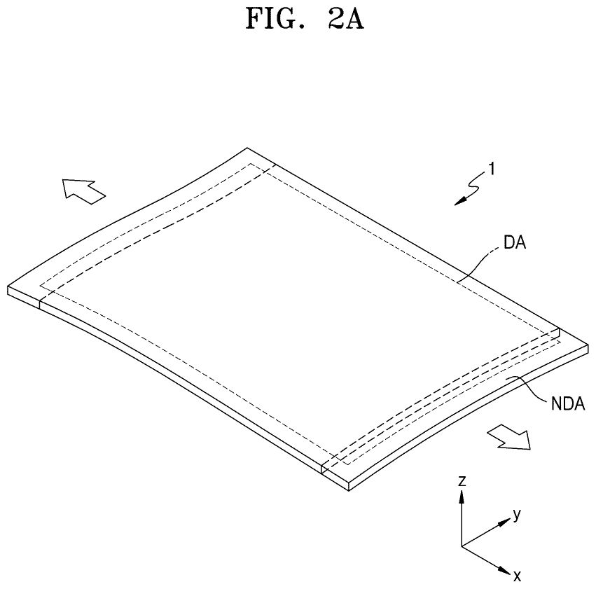

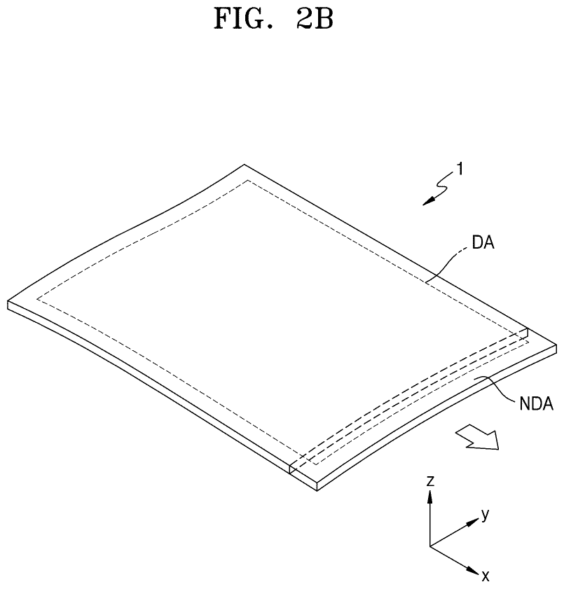

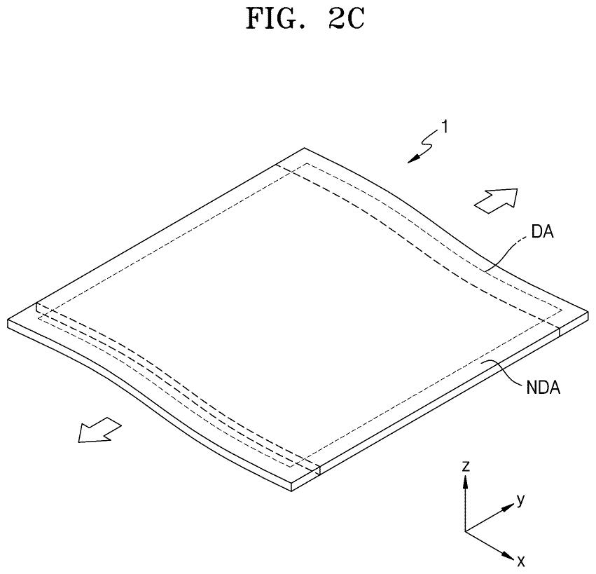

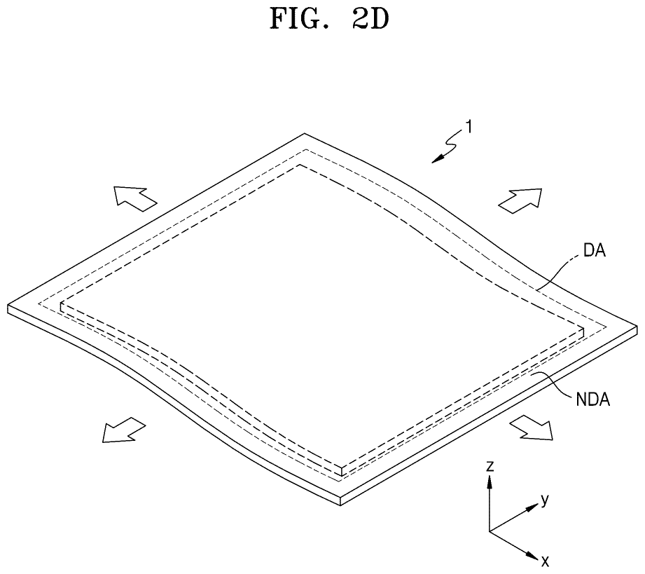

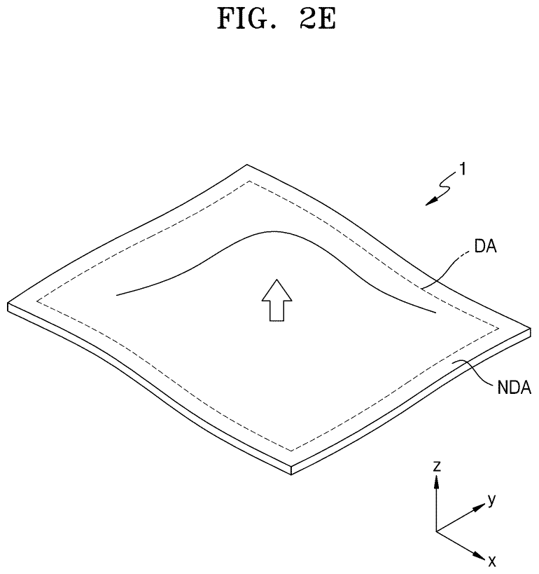

FIG. 1 is a schematic perspective view of a display device 1 according to one or more embodiments of the present disclosure. FIGS. 2A and 2B are perspective views each illustrating a state in which the display device 1 of FIG. 1 is stretched in a first direction. FIG. 2C is a perspective view illustrating a state in which the display device 1 of FIG. 1 is stretched in a second direction. FIG. 2D is a perspective view illustrating a state in which the display device 1 of FIG. 1 is stretched in the first direction and the second direction. FIG. 2E is a perspective view illustrating a state in which the display device 1 of FIG. 1 is stretched in a third direction.

Referring to FIG. 1, the display device 1 may include a display area DA and a non-display area NDA disposed around the display area along an edge or a periphery of the display area DA. The display area DA may include a plurality of pixels. The display device 1 may provide an image by using light emitted by the plurality of pixels. The non-display area NDA may be arranged outside the display area DA. The non-display area NDA is an area in which the pixels are not arranged and may entirely surround the display area DA.

The display device 1 may be stretched or shrunk in various directions. The display device 1 may be stretched in the first direction (e.g., an x direction and/or an −x direction) by an external force applied by an external object or a user. In one or more embodiments, as shown in FIGS. 2A and 2B, the display area DA and/or the non-display area NDA of the display device 1 may be stretched in the first direction (e.g., the x direction and/or the −x direction). For example, the display device 1 may be stretched in the x direction and the −x direction, as shown in FIG. 2A, or may be stretched in the x direction in a state in which one side of the display device 1 is fixed, as shown in FIG. 2B.

The display device 1 may be stretched in the second direction (e.g., a y direction and/or a −y direction) by an external force applied by an external object or a user. In one or more embodiments, as shown in FIG. 2C, the display area DA and/or the non-display area NDA of the display device 1 may be stretched in the y direction and the −y direction. In another embodiment, the display device 1 may be stretched in the y direction or the −y direction in a state in which one side of the display device 1 is fixed.

The display device 1 may be stretched in a plurality of directions, for example, the first direction (e.g., the x direction and/or the −x direction) and the second direction (e.g., the y direction and/or the −y direction), by an external force applied by an external object or a part of a human's body. As shown in FIG. 2D, the display area DA and/or the non-display area NDA of the display device 1 may be stretched in the ±x direction and the ±y direction.

The display device 1 may be stretched in the third direction (e.g., a z direction or a −z direction) by an external force applied by an external object or a part of a human's body. In one or more embodiments, FIG. 2E shows that a portion of the display device 1, for example, a partial area of the display area DA, protrudes in the z direction. In one or more embodiments, a portion of the display device 1, for example, a partial area of the display area DA, may protrude in the −z direction (or may be depressed in the z direction).

FIGS. 2A-2E show that the display device 1 is stretched in the first direction, the second direction, and/or the third direction, but the present disclosure is not limited thereto. In one or more embodiments, the display device 1 may be variously modified into irregular shapes, such as having two or more axes and being bent or twisted.

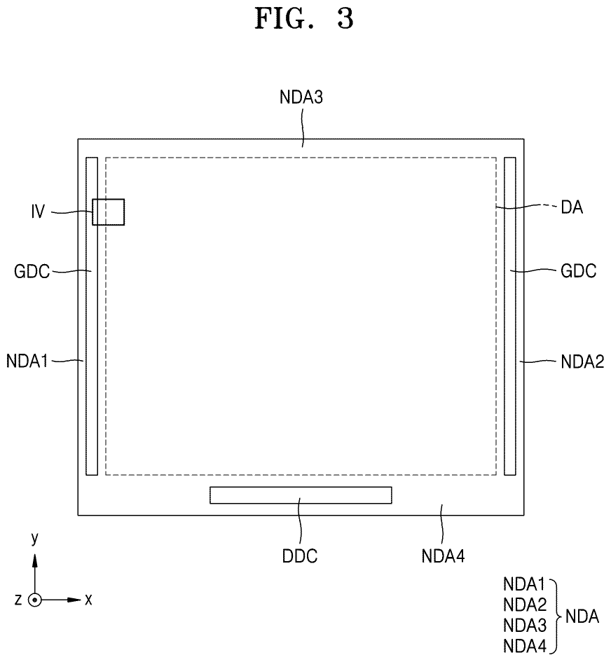

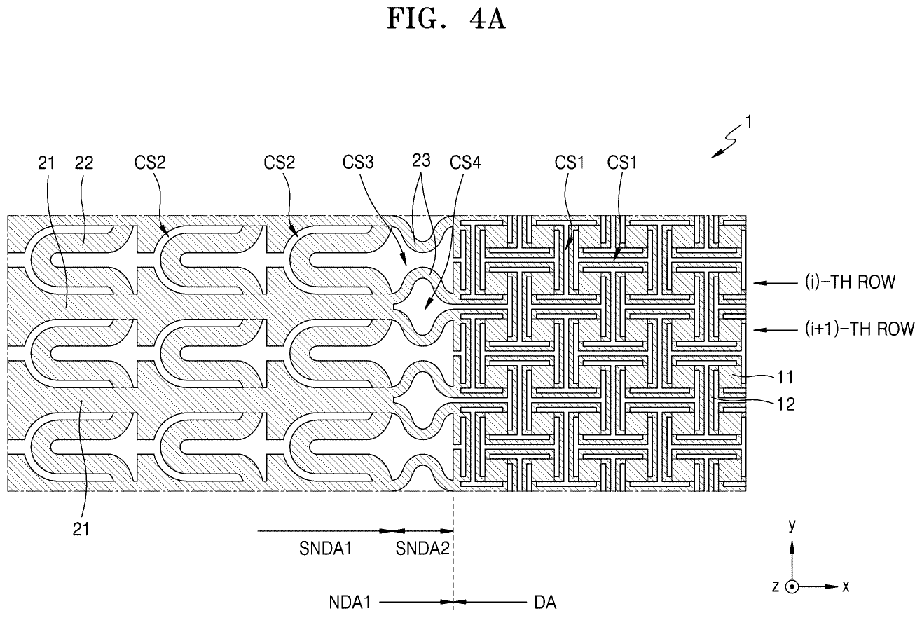

FIG. 3 is a schematic plan view of the display device 1 according to one or more embodiments of the present disclosure.

A plurality of pixels may be arranged in the display area DA of the display device 1. Each of the plurality of pixels may include sub-pixels emitting light of different colors. A light-emitting element corresponding to each sub-pixel may be arranged in the display area DA. A circuit configured to provide electrical signals to the light-emitting elements arranged in the display area DA and transistors electrically connected to the light-emitting elements may be positioned in the non-display area NDA around (e.g., surrounding) the display area DA. Gate driving circuits GDC may be respectively arranged in a first non-display area NDA1 and a second non-display area NDA2, wherein the first non-display area NDA1 and the second non-display area NDA2 are arranged on both sides of the display device with the display area DA therebetween. A gate driving circuit GDC may include drivers configured to provide electrical signals to a gate electrode of each of the transistors electrically connected to the light-emitting elements. FIG. 3 shows that the gate driving circuit GDC is arranged in each of the first non-display area NDA1 and the second non-display area NDA2, but the present disclosure is not limited thereto. In one or more embodiments, the gate driving circuit GDC may be arranged in any one of the first non-display area NDA1 and the second non-display area NDA2.

A data driving circuit DDC may be arranged in a third non-display area NDA3 and/or a fourth non-display area NDA4, which connects the first non-display area NDA1 to the second non-display area NDA2. In one or more embodiments, FIG. 3 shows that the data driving circuit DDC is arranged in the fourth non-display area NDA4. In one or more embodiments, the data driving circuit DDC may be arranged in each of the third non-display area NDA3 and the fourth non-display area NDA4.

FIG. 3 shows that the data driving circuit DDC is arranged in the fourth non-display area NDA4 of the display device 1, but the present disclosure is not limited thereto. In one or more embodiments, the display device 1 may further include a flexible circuit board electrically connected to a terminal arranged in the fourth non-display area NDA4, and the data driving circuit DDC may be arranged on the flexible circuit board described above.

In one or more embodiments, the elongation of the non-display area NDA may be equal to or less than the elongation of the display area DA. In one or more embodiments, the non-display area NDA may have a different elongation for each area. For example, the first non-display area NDA1, the second non-display area NDA2, and the third non-display area NDA3 may have substantially the same elongation, but the elongation of the fourth non-display area NDA4 may be less than the elongation of each of the first non-display area NDA1, the second non-display area NDA2, and the third non-display area NDA3. In the present disclosure, an elongation is a numerical value that represents a change in length (ΔL/L) by which the display device 1 may extend without physical damage to the display device 1 when an external force is applied to the display device 1. Herein, ΔL is a change in length of a display device, and L represents an initial length of the display device.

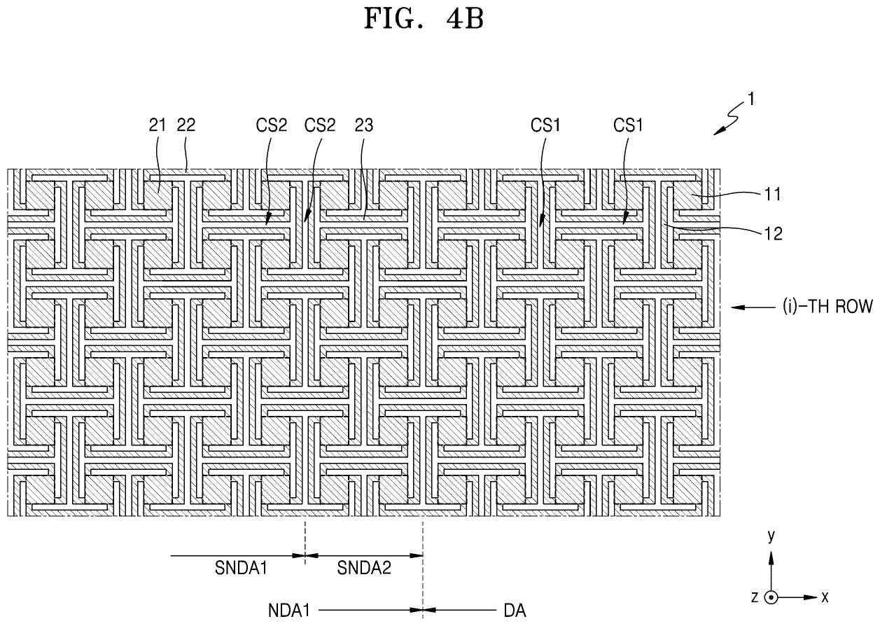

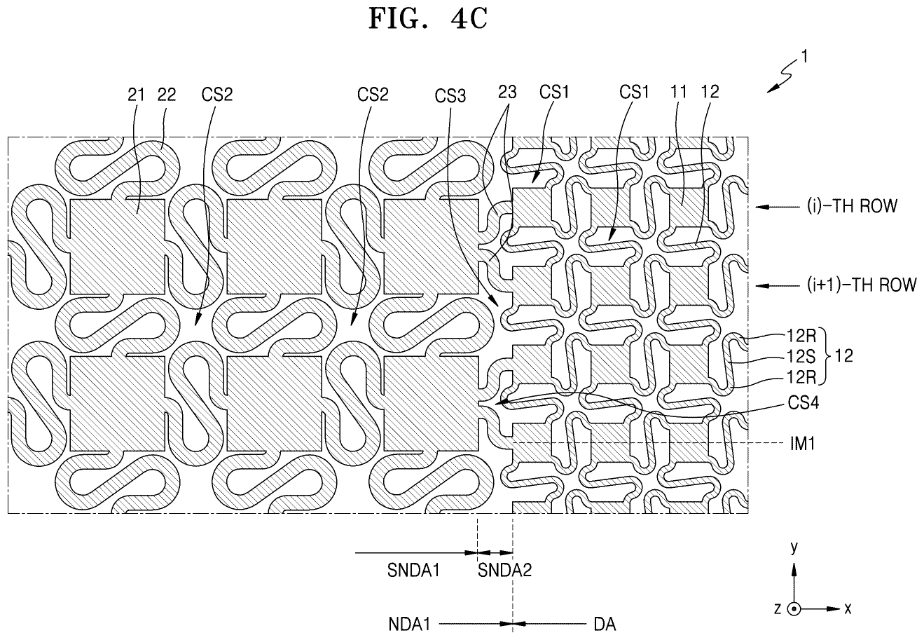

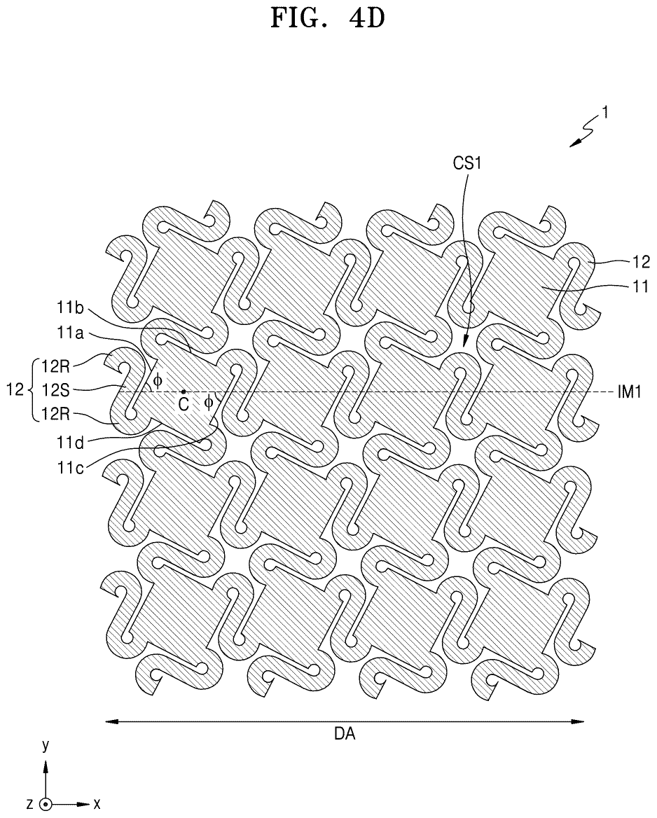

FIG. 4A is an enlarged plan view of a region IV of FIG. 3 as a portion of the display device 1 according to one or more embodiments of the present disclosure.

Referring to FIG. 4A, the display device 1 may include, in the display area DA, first island portions 11 spaced (e.g., spaced apart) from each other in the first direction (e.g., the x direction or the −x direction) and the second direction (e.g., the y direction or the −y direction), and first bridge portions 12 connecting adjacent first island portions 11 to each other.

Each first island portion 11 may be connected to a plurality of first bridge portions 12. For example, each first island portion 11 may be connected to four first bridge portions 12. Two first bridge portions 12 may be arranged on both sides of the first island portion 11 in the first direction (e.g., the x direction or the −x direction), and the remaining two first bridge portions 12 may be arranged on both sides of the first island portion 11 in the second direction (e.g., the y direction or the −y direction). In one or more embodiments, the four first bridge portions 12 may be respectively connected to four sides of the first island portion 11. Each of the four first bridge portions 12 may be adjacent to each of corners of the first island portion 11.

The first bridge portions 12 may be spaced (e.g., spaced apart) from each other by a first opening portion CS1 positioned between the first bridge portions 12. In one or more embodiments, a first opening portion CS1 having an approximately H shape and a first opening portion CS1 having an approximately I shape obtained by rotating the above-described H shape by 90 degrees may be alternately and repeatedly arranged along the first direction (e.g., the x direction or the −x direction) and the second direction (e.g., the y direction or the −y direction). Both end portions of each first bridge portion 12 are respectively connected to adjacent first island portions 11, but one side of each first bridge portion 12 may be spaced (e.g., spaced apart) from one side of an adjacent first island portion 11 and/or one side of another first bridge portion 12 by the first opening portion CS1.

The display device 1 may include, in a non-display area, for example, the first non-display area NDA1 shown in FIG. 4A, second island portions 21 spaced (e.g., spaced apart) from each other and second bridge portions 22 connecting adjacent second island portions 21 to each other.

Each second island portion 21 may extend in the first direction (e.g., the x direction or the −x direction). The second island portions 21 may be spaced (e.g., spaced apart) from each other in the second direction (e.g., the y direction or the −y direction) crossing the first direction (e.g., the x direction or the −x direction). Each second island portion 21 may include drivers of the gate driving circuit GDC (refer to FIG. 3) described above with reference to FIG. 3.

A second bridge portion 22 may have a serpentine shape. A length of the second bridge portion 22 may be greater than the shortest distance between adjacent second island portions 21 in the second direction (e.g., the y direction or the −y direction). In one or more embodiments, the second bridge portion 22 may have an approximately omega (Ω) shape that is convex toward the first direction (e.g., the x direction or the −x direction). The second bridge portions 22 may be arranged between adjacent second island portions 21 and may be spaced (e.g., spaced apart) from each other.

The second bridge portions 22 between adjacent second island portions 21 may be spaced (e.g., spaced apart) from each other by a second opening portion CS2. Second opening portions CS2 and the second bridge portions 22 may be alternately arranged between adjacent second island portions 21 along the first direction (e.g., the x direction or the −x direction). The second opening portions CS2 may have the same shape. Both end portions of each second bridge portion 22 are respectively connected to adjacent second island portions 21, but one side of each second bridge portion 22 may be spaced (e.g., spaced apart) from one side of an adjacent second island portion 21 and/or one side of another second bridge portion 22 by the second opening portion CS2.

A second island portion 21 arranged in the first non-display area NDA1 may correspond to the first island portions 11 of a plurality of rows arranged in the display area DA. For example, any one second island portion 21 arranged in the first non-display area NDA1 may correspond to the first island portions 11 arranged in an (i)-th row and the first island portions 11 arranged in an (i+1)-th row in the display area DA (where i is a positive number greater than 0). FIG. 4A shows that one second island portion 21 corresponds to two rows of first island portions 11, but the present disclosure is not limited thereto. In one or more embodiments, a second island portion 21 arranged in the first non-display area NDA1 may correspond to n rows of first island portions 11 arranged in the display area DA (where n is a positive number of 3 or more).

The non-display area, for example, the first non-display area NDA1, may include a first sub-non-display area SNDA1 in which the second island portions 21 and the second bridge portions 22 described above are arranged, and a second sub-non-display area SNDA2 between the first sub-non-display area SNDA1 and the display area DA. Third bridge portions 23 connecting the display area DA to the first sub-non-display area SNDA1 may be arranged in the second sub-non-display area SNDA2. One end portion of a third bridge portion 23 may be connected to the second island portion 21 and/or the second bridge portion 22, and the other end portion of the third bridge portion 23 may be connected to the first island portion 11 and/or the first bridge portion 12.

The third bridge portion 23 may have a serpentine shape. In one or more embodiments, the shape of the third bridge portion 23 may be different from the shape of each of the first bridge portion 12 and the second bridge portion 22. In one or more embodiments, as shown in FIG. 4A, the third bridge portion 23 may have an approximately omega (Ω) shape that is convex toward the second direction (e.g., the y direction or the −y direction). Adjacent third bridge portions 23 arranged in the second direction (e.g., the y direction or the −y direction) may have structures that are symmetrical to each other, for example one of the adjacent third bridge portions 23 arranged in the second direction (e.g., the y direction or the −y direction) may be convex in the y direction, and the other one may be convex in the −y direction). A structure in third opening portions CS3 and fourth opening portions CS4, which have different shapes, are repeated and may be provided between the third bridge portions 23. A width of the third bridge portion 23 may be different from a width of the first bridge portion 12 and a width of the second bridge portion 22. In one or more embodiments, the width of the third bridge portion 23 may be greater than the width of the first bridge portion 12 and may be less than the width of the second bridge portion 22.

FIG. 4A shows that the second island portion 21 and the second bridge portion 22 in the non-display area (e.g., the first non-display area NDA1) have different shapes from the first island portion 11 and the first bridge portion 12 in the display area DA, respectively. In one or more embodiments of the present disclosure, the second island portion 21 and the second bridge portion 22 in the non-display area may have the same shapes as the first island portion 11 and the first bridge portion 12 in the display area DA, respectively.

FIG. 4B is an enlarged view of the region IV of FIG. 3 as a portion of the display device 1 according to one or more embodiments of the present disclosure.

Referring to FIG. 4B, the display device 1 may include, in the display area DA, the first island portions 11 spaced (e.g., spaced apart) from each other and the first bridge portions 12 spaced (e.g., spaced apart) from each other by the first opening portion CS1 and connecting adjacent first island portions 11 to each other. The structure of the display area DA of FIG. 4B may be the same as the structure of the display area DA described above with reference to FIG. 4A.

The display device 1 may include the second island portions 21 and the second bridge portions 22, which are arranged in the non-display area, for example, the first non-display area NDA1. In one or more embodiments, the second island portions 21 and the second bridge portions 22 may have substantially the same shapes as the first island portions 11 and the first bridge portions 12, respectively.

The second island portions 21 may be spaced (e.g., spaced apart) from each other in the first direction (e.g., the x direction or the −x direction) and the second direction (e.g., the y direction or the −y direction) in the non-display area, for example, the first non-display area NDA1. The second bridge portions 22 may be respectively connected to adjacent second island portions 21. The second bridge portions 22 may be spaced (e.g., spaced apart) from each other by the second opening portion CS2 positioned between the second bridge portions 22.

The second opening portion CS2 may have substantially the same shape as the first opening portion CS1. For example, a second opening portion CS2 having an approximately H shape and a second opening portion CS2 having an approximately I shape may be alternately and repeatedly arranged in the non-display area, for example, the first non-display area NDA1. Both end portions of each second bridge portion 22 are respectively connected to adjacent second island portions 21, but one side of each second bridge portion 22 may be spaced (e.g., spaced apart) from one side of an adjacent second island portion 21 and/or one side of another second bridge portion 22 by the second opening portion CS2.

Each second island portion 21 may be connected to four second bridge portions 22. Each second island portion 21 may include drivers of the gate driving circuit GDC (refer to FIG. 3) described above with reference to FIG. 3.

The second island portions 21 of one row arranged in the first non-display area NDA1 may correspond to the first island portions 11 of one row arranged in the display area DA. For example, the second island portions 21 arranged in an (i)-th row in the first direction (e.g., the x direction or the −x direction) in the first non-display area NDA1 may correspond to the first island portions 11 arranged in the same row in the display area DA, for example, the (i)-th row (where i is a positive number greater than 0).

The display device 1 may include the third bridge portions 23 arranged in the second sub-non-display area SNDA2 connecting the display area DA to the first sub-non-display area SNDA1. The non-display area, for example, the first non-display area NDA1, may include the first sub-non-display area SNDA1 in which the second island portions 21 and the second bridge portions 22 are arranged, and the second sub-non-display area SNDA2 including the third bridge portions 23 and positioned between the first sub-non-display area SNDA1 and the display area DA. The third bridge portion 23 may be substantially the same as the first bridge portion 12 and the second bridge portion 22. For example, the width of the third bridge portion 23 may be equal to the width of the first bridge portion 12 and the width of the second bridge portion 22.

FIG. 4C is an enlarged plan view of the region IV of FIG. 3 as a portion of the display device 1 according to one or more embodiments of the present disclosure.

Referring to FIG. 4C, the display device 1 may include, in the display area DA, the first island portions 11 spaced (e.g., spaced apart) from each other in the first direction (e.g., the x direction or the −x direction) and the second direction (e.g., the y direction or the −y direction), and the first bridge portions 12 connecting adjacent first island portions 11 to each other.

The first bridge portions 12 may be arranged to be spaced (e.g., spaced apart) from each other by the first opening portion CS1 positioned between the first bridge portions 12. The first bridge portion 12 may have a serpentine shape. For example, as shown in FIG. 4C, the first bridge portion 12 may have an approximate shape of ‘the letter S’, such as including two round portions 12R and a straight-line portion 12S between the two round portions 12R.

Each first island portion 11 may be connected to the plurality of first bridge portions 12. For example, each first island portion 11 may be connected to four first bridge portions 12. Two first bridge portions 12 may be arranged on both sides of the first island portion 11 in the first direction (e.g., the x direction or the −x direction), and the remaining two first bridge portions 12 may be arranged on both sides of the first island portion 11 in the second direction (e.g., the y direction or the −y direction). The four first bridge portion 12 may be respectively connected to four sides of the first island portion 11. Each of the four first bridge portions 12 may be adjacent to each of the corners of the first island portion 11.

The display device 1 may include, in the non-display area, for example, the first non-display area NDA1 shown in FIG. 4C, the second island portions 21 spaced (e.g., spaced apart) from each other in the first direction (e.g., the x direction or the −x direction) and the second direction (e.g., the y direction or the −y direction), and the second bridge portions 22 connecting adjacent second island portions 21 to each other.

The second bridge portions 22 may be arranged to be spaced (e.g., spaced apart) from each other by the second opening portion CS2 positioned between the second bridge portions 22. The second bridge portion 22 may have a serpentine shape. For example, as shown in FIG. 4C, the second bridge portion 22 may have an approximate shape of ‘the letter S.’ The size and/or width of the second bridge portion 22 may be different from the size and/or width of the first bridge portion 12. For example, the size and/or width of the second bridge portion 22 may be greater than the size and/or width of the first bridge portion 12. The radius of curvature of a rounded portion of the second bridge portion 22 may be different from the radius of curvature of a rounded portion (e.g., 12R) of the first bridge portion 12. For example, the radius of curvature of the rounded portion of the second bridge portion 22 may be greater than the radius of curvature of the rounded portion (e.g., 12R) of the first bridge portion 12.

Each second island portion 21 may be connected to a plurality of second bridge portions 22. Each second island portion 21 may be connected to four second bridge portions 22. Two second bridge portions 22 may be respectively arranged on both sides of the second island portion 21 in the first direction (e.g., the x direction or the −x direction), and the remaining two second bridge portions 22 may be respectively arranged on both sides of the second island portion 21 in the second direction (e.g., the y direction or the −y direction). In one or more embodiments, the four second bridge portions 22 may be respectively connected to four sides of the second island portion 21. Each second bridge portion 22 may be connected to a central portion of each side of the second island portion 21.

The second island portions 21 of one row arranged in the first non-display area NDA1 may correspond to the first island portions 11 of a plurality of rows arranged in the display area DA. For example, the second island portions 21 of one row arranged in the first non-display area NDA1 may correspond to the first island portions 11 arranged in the (i)-th row and the first island portions 11 arranged in the (i+1)-th row in the display area DA (where i is a positive number greater than 0). In one or more embodiments, the second island portions 21 of one row may correspond to n rows of the first island portions 11 (where n is a positive number of 3 or more).

The non-display area, for example, the first non-display area NDA1, may include the first sub-non-display area SNDA1 in which the second island portions 21 and the second bridge portions 22 described above are arranged, and the second sub-non-display area SNDA2 between the first sub-non-display area SNDA1 and the display area DA. The third bridge portions 23 connecting the display area DA to the first sub-non-display area SNDA1 may be arranged in the second sub-non-display area SNDA2. One end portion of the third bridge portion 23 may be connected to the second island portion 21, and the other end portion of the third bridge portion 23 may be connected to the first island portion 11. For example, one end portion of the third bridge portion 23 may be connected to the central portion of one side of the second island portion 21, and the other end portion of the third bridge portion 23 may be connected to the central portion of one side of the first island portion 11.

The third bridge portion 23 may have a serpentine shape. In one or more embodiments, the shape of the third bridge portion 23 may be different from the shape of each of the first bridge portion 12 and the second bridge portion 22. The width of the third bridge portion 23 may be different from the width of the first bridge portion 12 and the width of the second bridge portion 22. The width of the third bridge portion 23 may be greater than the width of the first bridge portion 12 and may be less than the width of the second bridge portion 22. The third opening portions CS3 and the fourth opening portions CS4, which have different shapes, may be alternately arranged between the third bridge portions 23 along the second direction (e.g., the y direction or the −y direction).

FIG. 4D is an enlarged plan view of the display area DA of FIG. 3 as a portion of the display device 1 according to one or more embodiments of the present disclosure.

Referring to FIG. 4D, the display device 1 may include, in the display area DA, the first island portions 11 spaced (e.g., spaced apart) from each other in the first direction (e.g., the x direction or the −x direction) and the second direction (e.g., the y direction or the −y direction), and the first bridge portions 12 connecting adjacent first island portions 11 to each other. The first bridge portions 12 may be arranged to be spaced (e.g., spaced apart) from each other by the first opening portion CS1 positioned between the first bridge portions 12.

In one or more embodiments, at least one of the sides of the first island portion 11 may be oblique with respect to a virtual line connecting the centers C of the first island portions 11 in the first direction (e.g., the x direction or the −x direction) and/or the second direction (e.g., the y direction or the −y direction). In this regard, FIG. 4D shows that each first island portion 11 includes first to fourth sides 11a, 11b, 11c, and 11d, and the first to fourth sides 11a, 11b, 11c, and 11d extend in a direction oblique to a first virtual line IM1 connecting the centers C of the first island portions 11. FIG. 4D shows that the first virtual line IM1 extends in the first direction (e.g., the x direction or the −x direction), but the first virtual line IM1 may extend in the second direction (e.g., the y direction or the −y direction).

In one or more embodiments, the first side 11a and the third side 11c, which are parallel to each other, may cross the first virtual line IM1. A smaller angle (hereinafter referred to as a minor angle φ) from among angles formed by the first side 11a and the first virtual line IM1 may be greater than 0 degrees and less than 90 degrees. A minor angle φ formed by the third side 11c and the first virtual line IM1 may be greater than 0 degrees and less than 90 degrees.

The first island portion 11 may be connected to the plurality of first bridge portions 12. For example, the first island portion 11 may be connected to four first bridge portions 12. Two first bridge portions 12 may be arranged on both sides of the first island portion 11 in the first direction (e.g., the x direction or the −x direction), and the remaining two first bridge portions 12 may be arranged on both sides of the first island portion 11 in the second direction (e.g., the y direction or the −y direction).

The first bridge portion 12 may have a serpentine shape. For example, as shown in FIG. 4D, the first bridge portion 12 may have an approximate shape of ‘the letter S’, such as including two round portions 12R and a straight-line portion 12S between the two round portions 12R.

In one or more embodiments, the straight-line portion 12S may be substantially parallel to an edge of an adjacent first island portion 11, as shown in FIG. 4D. For example, the straight-line portions 12S of the first bridge portions 12 respectively positioned on both sides of the first island portion 11 in the first direction (e.g., the x direction or the −x direction) may be substantially parallel to the sides (e.g., the first side 11a and the third side 11c) of the first island portion 11. The straight-line portions 12S of the first bridge portions 12 respectively positioned on both sides of the first island portion 11 in the second direction (e.g., the y direction or the −y direction) may be substantially parallel to the sides (e.g., the second side 11b and the fourth side 11d) of the first island portion 11.

Each of the first island portions 11 shown in FIG. 4D may be understood as that the first island portions 11 shown in FIG. 4C are rotated with respect to the centers C by a first angle (e.g., an acute angle). Accordingly, at least one of the sides of the first island portion 11 may be oblique with respect to a virtual line connecting the centers C of the first island portions 11 in the first direction (e.g., the x direction or the −x direction) and/or the second direction (e.g., the y direction or the −y direction. According to the arrangement of the first island portion 11 and/or the structure of the first bridge portion 12 as described above, an area of the first opening portion CS1 shown in FIG. 4D may be relatively less than an area of the first opening portion CS1 shown in FIG. 4C, and thus, the display device 1 according to the embodiment shown in FIG. 4D may provide images with relatively high resolution.

FIG. 4D shows that the straight-line portion 12S of the first bridge portion 12 is substantially parallel to the side of a first island portion 11 adjacent to the straight-line portion 12S, but the present disclosure is not limited thereto. In one or more embodiments, the straight-line portion 12S of the first bridge portion 12 may be oblique with respect to the side of a first island portion 11 adjacent to the straight-line portion 12S, as shown in FIG. 4C.

In one or more embodiments, the structure of the first non-display area NDA1 (refer to FIG. 3) of the display device 1, which is not disclosed in FIG. 4D, may be the same as the structure of the display area DA shown in FIG. 4D. In one or more embodiments, the structure of the first non-display area NDA1 (refer to FIG. 3) of the display device 1, which is not disclosed in FIG. 4D, is substantially the same as the structure of the display area DA shown in FIG. 4D, but an area of a second island portion arranged in the first non-display area NDA1 (refer to FIG. 3) may be greater than the area of the first island portion 11. In this case, one second island portion may correspond to the plurality of first island portions 11 arranged in adjacent rows as described with reference to FIG. 4C. In one or more embodiments, the structure of the first non-display area NDA1 (refer to FIG. 3) of the display device 1, which is not disclosed in FIG. 4D, may be substantially the same as the structure of the first non-display area NDA1 shown in any one FIGS. 4A-4C . As such, the structure of the first non-display area NDA1 (refer to FIG. 3) may be selected in various ways within the range disclosed in the present disclosure.

FIG. 5 is a schematic cross-sectional view of the first island portion 11 and the first bridge portion 12, which are arranged in the display area DA of the display device 1 according to one or more embodiments of the present disclosure.

Referring to FIG. 5, the first island portion 11 and the first bridge portion 12, which are arranged in the display area DA, may be spaced (e.g., spaced apart) from each other with the first opening portion CS1 between the first island portion 11 and the first bridge portion 12. The first island portion 11 may include light-emitting elements LED and a circuit electrically connected to the light-emitting elements LED and configured to drive the light-emitting elements LED, for example, a pixel driving circuit unit PC, and the first bridge portion 12 may include a line WL electrically connected to pixel driving circuit units PC respectively arranged in adjacent first island portions 11.

When looking at the first island portion 11, a buffer layer 111 including an inorganic insulating material may be arranged on a substrate 100, and the pixel driving circuit unit PC may be arranged on the buffer layer 111. An insulating layer IL including an inorganic insulating material and/or an organic insulating material may be arranged between the pixel driving circuit unit PC and a light-emitting element LED. The light-emitting element LED may be arranged on the insulating layer IL and may be electrically connected to a corresponding pixel driving circuit unit PC. The light-emitting elements LED may emit light of different colors or the same color. In one or more embodiments, the light-emitting elements LED may respectively emit red, green, and blue light. In one or more embodiments, the light-emitting elements LED may emit white light. In one or more embodiments, the light-emitting elements LED may respectively emit red, green, blue, and white light.

The substrate 100 may include a polymer resin, such as polyethersulfone, polyarylate, polyetherimide, polyethylene naphthalate, polyethylene terephthalate, polyphenylene sulfide, polyimide, polycarbonate, cellulose triacetate, and/or cellulose acetate propionate. In one or more embodiments, the substrate 100 may be a single layer including the polymer resin described above. In one or more embodiments, the substrate 100 may have a multi-layered structure including a base layer including the polymer resin described above, and a barrier layer including an inorganic insulating material. The substrate 100 including the polymer resin may be flexible, rollable, and/or bendable.

In one or more embodiments, FIG. 5 shows three pixel driving circuit units PC arranged in each first island portion 11 and three light-emitting elements LED are connected to respective pixel driving circuit units PC, but the present disclosure is not limited thereto. In one or more embodiments, the number of each of the pixel driving circuit units PC and the light-emitting elements LED, which are arranged in the first island portion 11, may be one, two, or four or more.

An encapsulation layer 300 may be arranged on the light-emitting element LED and may protect the light-emitting element LED from external force and/or moisture penetration. The encapsulation layer 300 may include an inorganic encapsulation layer and/or an organic encapsulation layer. In one or more embodiments, the encapsulation layer 300 may include a structure in which an inorganic encapsulation layer including an inorganic insulating material, an organic encapsulation layer including an organic insulating material, and an inorganic encapsulation layer including an inorganic insulating material are stacked. In one or more embodiments, the encapsulation layer 300 may include an organic material such as resin. In one or more embodiments, the encapsulation layer 300 may include urethane epoxy acrylate. The encapsulation layer 300 may include a photosensitive material, for example, a material such as photoresist.

When looking at the first bridge portion 12, the insulating layer IL including an organic insulating material may be arranged on the substrate 100. When the display device 1 is stretched, the first bridge portion 12, which is relatively deformed, may not include a layer including an inorganic insulating material that is prone to cracks, unlike the first island portion 11.

In one or more embodiments, the substrate 100 corresponding to the first bridge portion 12 may have the same stacked structure as the substrate 100 corresponding to the first island portion 11. In one or more embodiments, the substrate 100 corresponding to the first bridge portion 12 and the substrate 100 corresponding to the first island portion 11 may be polymer resin layers formed together in the same process. In one or more embodiments, the substrate 100 corresponding to the first bridge portion 12 may have a stacked structure different from that of the substrate 100 corresponding to the first island portion 11. In one or more embodiments, the substrate 100 corresponding to the first island portion 11 may have a multi-layered structure including a base layer including a polymer resin and a barrier layer including an inorganic insulating material, and the substrate 100 corresponding to the first bridge portion 12 may have a structure of a polymer resin layer without a layer including an inorganic insulating material.

As described above, lines WL of the first bridge portion 12 may be signal lines (e.g., gate lines, data lines, and/or the like) for providing electrical signals to transistors included in the pixel driving circuit unit PC of the first island portion 11, or may be voltage lines (e.g., driving voltage lines, initialization voltage lines, and/or the like) for providing voltages. The encapsulation layer 300 may also be arranged in the first bridge portion 12. In one or more embodiments, the encapsulation layer 300 may not be present in the first bridge portion 12.

Referring to FIGS. 4A-4D , and 5, the substrate 100 corresponding to the first island portion 11 and the substrate 100 corresponding to the first bridge portion 12 may be connected to each other. In other words, the plan views previously shown in FIGS. 4A-4D may be substantially the same as the plan view of the substrate 100 of FIG. 5. That is, the substrate 100 may include an area corresponding to the first island portion 11, an area corresponding to the first bridge portion 12, an opening 100OP1 having the same shape as the first opening portion CS1.

Similarly, the encapsulation layer 300 corresponding to the first island portion 11 and the encapsulation layer 300 corresponding to the first bridge portion 12 may be connected to each other. For example, the plan views previously shown in FIGS. 4A-4D may be substantially the same as the plan view of the encapsulation layer 300. In other words, the encapsulation layer 300 may include an area corresponding to the first island portion 11, an area corresponding to the first bridge portion 12, and an opening 300OP1 having the same shape as the first opening portion CS1.

A circuit-light-emitting element layer 200 between the substrate 100 and the encapsulation layer 300 may include the buffer layer 111, the pixel driving circuit unit PC, the line WL, the insulating layer IL, and the light-emitting element LED. Similar to the substrate 100, the plan views previously shown in FIGS. 4A-4D may be substantially the same as the plan view of the circuit-light-emitting element layer 200. In other words, the circuit-light-emitting element layer 200 may include an opening 200OP1 having the same shape as the first opening portion CS1.

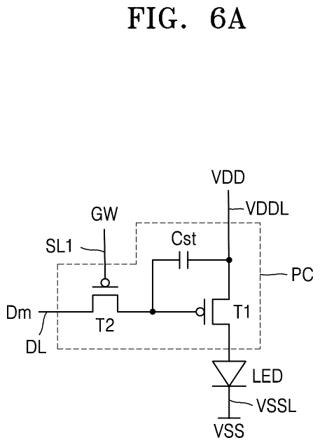

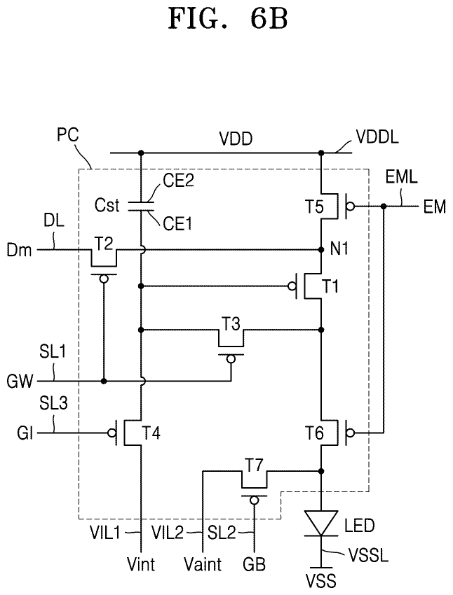

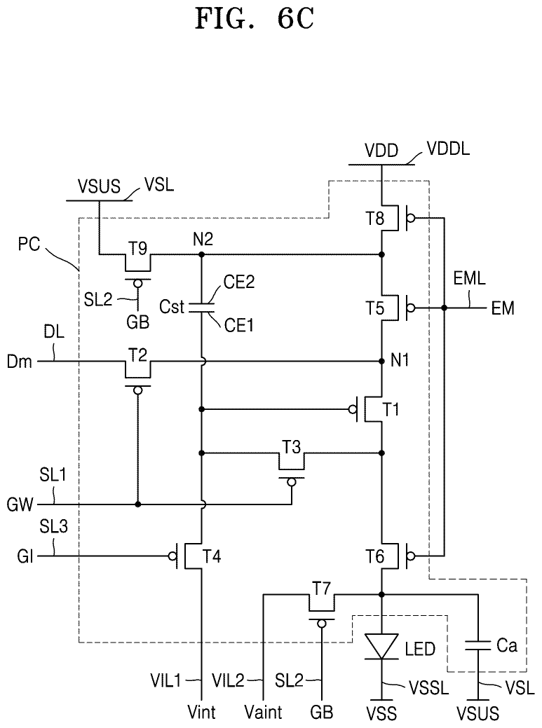

FIGS. 6A-6C are equivalent circuit diagrams each illustrating a sub-pixel of the display device 1 according to one or more embodiments of the present disclosure.

Referring to FIG. 6A, the light-emitting element LED corresponding to the sub-pixel may be electrically connected to the pixel driving circuit unit PC, and the pixel driving circuit unit PC may include a first transistor T1, a second transistor T2, and a storage capacitor Cst. The pixel driving circuit unit PC may be electrically connected to signal lines and voltage lines. The signal lines may include a gate line, such as a first scan line SL1, and a data line DL, and the voltage lines may include a first voltage line VDDL and a second voltage line VSSL.

The second transistor T2 may be electrically connected to the first scan line SL1 and the data line DL. The first scan line SL1 may provide a first scan signal GW to a gate electrode of the second transistor T2. The second transistor T2 may be configured to transmit, to the first transistor T1, a data signal Dm input from the data line DL according to the first scan signal GW input from the first scan line SL1.

The storage capacitor Cst may be electrically connected to the second transistor T2, a gate electrode of the first transistor T1, and the first voltage line VDDL, and may store a voltage corresponding to the difference between a voltage received from the second transistor T2 and a first power voltage VDD supplied by the first voltage line VDDL.

The first transistor T1 is a driving transistor, which may control a driving current flowing through the light-emitting element LED. The first transistor T1 may be connected to the first voltage line VDDL and the storage capacitor Cst. The first transistor T1 may control the driving current flowing through the light-emitting element LED from the first voltage line VDDL in accordance to a voltage value stored in the storage capacitor Cst. The light-emitting element LED may emit light having a certain brightness according to the driving current. A first electrode of the light-emitting element LED may be electrically connected to the first transistor T1, and a second electrode thereof may be electrically connected to the second voltage line VSSL providing a second power voltage VSS.

Although FIG. 6A illustrates that the pixel driving circuit unit PC includes two transistors and one storage capacitor, in one or more embodiments, the pixel driving circuit unit PC may include three or more transistors.

Referring to FIG. 6B, the pixel driving circuit unit PC may include the first transistor T1, the second transistor T2, a third transistor T3, a fourth transistor T4, a fifth transistor T5, a sixth transistor T6, a seventh transistor T7, and the storage capacitor Cst.

The pixel driving circuit unit PC is electrically connected to signal lines and voltage lines. The signal lines may include gate lines, such as the first scan line SL1, a second scan line SL2, a third scan line SL3, and an emission control line EML, and the data line DL. The voltage lines may include first and second initialization voltage lines VIL1 and VIL2, the first voltage line VDDL, and the second voltage line VSSL.

The first voltage line VDDL may be configured to transmit the first power voltage VDD to the first transistor T1. The first initialization voltage line VIL1 may be configured to transmit, to the pixel driving circuit unit PC, a first initialization voltage Vint initializing the first transistor T1. The second initialization voltage line VIL2 may be configured to transmit, to the pixel driving circuit unit PC, a second initialization voltage Vaint initializing the first electrode of the light-emitting element LED.

The first transistor T1 may be electrically connected to the first voltage line VDDL via the fifth transistor T5 and may be electrically connected to the light-emitting element LED via the sixth transistor T6. The first transistor T1 serves as a driving transistor and receives the data signal Dm in response to a switching operation of the second transistor T2 to supply a driving current to the light-emitting element LED.

The second transistor T2 is a data write transistor, which is electrically connected to the first scan line SL1 and the data line DL. The second transistor T2 is electrically connected to the first voltage line VDDL via the fifth transistor T5. The second transistor T2 is turned on in response to the first scan signal GW received through the first scan line SL1 and performs a switching operation of delivering the data signal Dm delivered by the data line DL to a first node N1.

The third transistor T3 is electrically connected to the first scan line SL1 and is electrically connected to the light-emitting element LED via the sixth transistor T6. The third transistor T3 may be turned on in response to the first scan signal GW received through the first scan line SL1 to diode-connect the first transistor T1 as the third transistor T3 is connected between a second electrode and a gate electrode of the first transistor T1.

The fourth transistor T4 is a first initialization transistor, which is electrically connected to the third scan line SL3 and the first initialization voltage line VIL1. The fourth transistor T4 is turned on in response to a third scan signal GI received through the third scan line SL3 to deliver the first initialization voltage Vint from the first initialization voltage line VIL1 to the gate electrode of the first transistor T1 to initialize a voltage of the gate electrode of the first transistor T1. The third scan signal GI may correspond to a first scan signal of another pixel driving circuit unit arranged in a previous row of the corresponding pixel driving circuit unit PC.

The fifth transistor T5 may be an operation control transistor, and the sixth transistor T6 may be an emission control transistor. The fifth transistor T5 and the sixth transistor T6 are electrically connected to the emission control line EML and are concurrently (e.g., simultaneously) turned on in response to an emission control signal EM received through the emission control line EML to form a current path so that a driving current may flow in a direction from the first voltage line VDDL to the light-emitting element LED.

The seventh transistor T7 is a second initialization transistor, which may be electrically connected to the second scan line SL2, the second initialization voltage line VIL2, and the sixth transistor T6. The seventh transistor T7 may be turned on in response to a second scan signal GB received through the second scan line SL2 to deliver the second initialization voltage Vaint from the second initialization voltage line VIL2 to the first electrode of the light-emitting element LED to initialize the first electrode of the light-emitting element LED.

The storage capacitor Cst may include a first electrode CE1 and a second electrode CE2. The first electrode CE1 is electrically connected to the gate electrode of the first transistor T1, and the second electrode CE2 is electrically connected to the first voltage line VDDL. The storage capacitor Cst may maintain a voltage applied to the gate electrode of the first transistor T1 by storing and maintaining a voltage corresponding to the difference between voltages of both ends of the first voltage line VDDL and the gate electrode of the first transistor T1.

Referring to FIG. 6C, the pixel driving circuit unit PC may include the first transistor T1, the second transistor T2, the third transistor T3, the fourth transistor T4, the fifth transistor T5, the sixth transistor T6, the seventh transistor T7, an eighth transistor T8, a ninth transistor T9, the storage capacitor Cst, and an auxiliary capacitor Ca.

The pixel driving circuit unit PC is electrically connected to signal lines and voltage lines. The signal lines may include gate lines, such as the first scan line SL1, the second scan line SL2, the third scan line SL3, and the emission control line EML, and the data line DL. The voltage lines may include the first and second initialization voltage lines VIL1 and VIL2, a maintenance voltage line VSL, the first voltage line VDDL, and the second voltage line VSSL.

The first voltage line VDDL may be configured to transmit the first power voltage VDD to the first transistor T1. The first initialization voltage line VIL1 may be configured to transmit, to the pixel driving circuit unit PC, the first initialization voltage Vint initializing the first transistor T1. The second initialization voltage line VIL2 may be configured to transmit, to the pixel driving circuit unit PC, a second initialization voltage Vaint initializing the first electrode of the light-emitting element LED. The maintenance voltage line VSL may provide a maintenance voltage VSUS to a second node N2, for example, the second electrode CE2 of the storage capacitor Cst, during an initialization period and a data write period.

The first transistor T1 may be electrically connected to the first voltage line VDDL via the fifth transistor T5 and the eighth transistor T8, and may be electrically connected to the light-emitting element LED via the sixth transistor T6. The first transistor T1 may serve as a driving transistor and receive the data signal Dm in response to a switching operation of the second transistor T2 to supply a driving current to the light-emitting element LED.

The second transistor T2 is electrically connected to the first scan line SL1 and the data line DL, and is electrically connected to the first voltage line VDDL via the fifth transistor T5 and the eighth transistor T8. The second transistor T2 is turned on in response to the first scan signal GW received through the first scan line SL1 and performs a switching operation of transmitting the data signal Dm transmitted through the data line DL to the first node N1.

The third transistor T3 is electrically connected to the first scan line SL1 and is electrically connected to the light-emitting element LED via the sixth transistor T6. The third transistor T3 may be turned on in response to the first scan signal GW received through the first scan line SL1 to diode-connect the first transistor T1 (e.g., as the third transistor T3 is connected between a second electrode and a gate electrode of the first transistor T1), thereby compensating for a threshold voltage of the first transistor T1.

The fourth transistor T4 is electrically connected to the third scan line SL3 and the first initialization voltage line VIL1 and turned on in response to the third scan signal GI received through the third scan line SL3 to deliver the first initialization voltage Vint from the first initialization voltage line VIL1 to the gate electrode of the first transistor T1 to initialize a voltage of the gate electrode of the first transistor T1. The third scan signal GI may correspond to a first scan signal of another pixel driving circuit unit arranged in a previous row of the corresponding pixel driving circuit unit PC.

The fifth transistor T5, the sixth transistor T6, and the eighth transistor T8 are electrically connected to the emission control line EML and concurrently (e.g., simultaneously) turned on in response to the emission control signal EM received through the emission control line EML to form a current path so that the driving current may flow in a direction from the first voltage line VDDL to the light-emitting element LED.

The seventh transistor T7 is a second initialization transistor, which may be electrically connected to the second scan line SL2, the second initialization voltage line VIL2, and the sixth transistor T6. The seventh transistor T7 is turned on in response to the second scan signal GB received through the second scan line SL2 to deliver the second initialization voltage Vaint from the second initialization voltage line VIL2 to the first electrode of the light-emitting element LED to initialize the first electrode of the light-emitting element LED.

The ninth transistor T9 may be electrically connected to the second scan line SL2, the second electrode CE2 of the storage capacitor Cst, and the maintenance voltage line VSL. The ninth transistor T9 may be turned on in response to the second scan signal GB received through the second scan line SL2 to deliver the maintenance voltage VSUS to the second node N2, for example, the second electrode CE2 of the storage capacitor Cst, during an initialization period and a data write period.

Each of the eighth transistor T8 and the ninth transistor T9 may be electrically connected to the second node N2, for example, the second electrode CE2 of the storage capacitor Cst. In one or more embodiments, the eighth transistor T8 may be turned off and the ninth transistor T9 may be turned on during the initialization period and the data write period, and the eighth transistor T8 may be turned on and the ninth transistor T9 may be turned off during an emission period. Because the maintenance voltage VSUS is transmitted to the second node N2 during the initialization period and the data write period, the brightness uniformity (for example, long-range uniformity (LRU)) of a display device according to a voltage drop of the first voltage line VDDL may be improved.

The storage capacitor Cst may include the first electrode CE1 and the second electrode CE2. The first electrode CE1 is electrically connected to the gate electrode of the first transistor T1, and the second electrode CE2 is electrically connected to the eighth transistor T8 and the ninth transistor T9.

The auxiliary capacitor Ca may be electrically connected to the sixth transistor T6, the maintenance voltage line VSL, and the first electrode of the light-emitting element LED. The auxiliary capacitor Ca may store and maintain a voltage corresponding to a voltage difference between the first electrode of the light-emitting element LED and the maintenance voltage line VSL while the seventh transistor T7 and the ninth transistor T9 are turned on, so that an increase of black brightness, when the sixth transistor T6 is turned off, may be prevented.

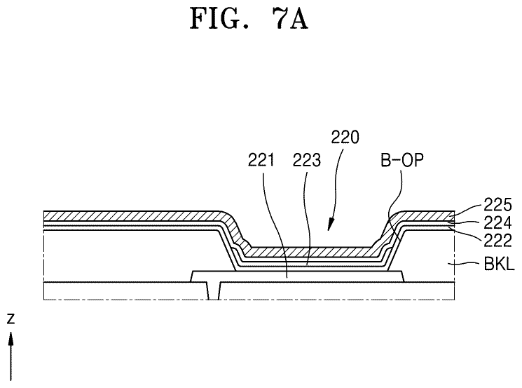

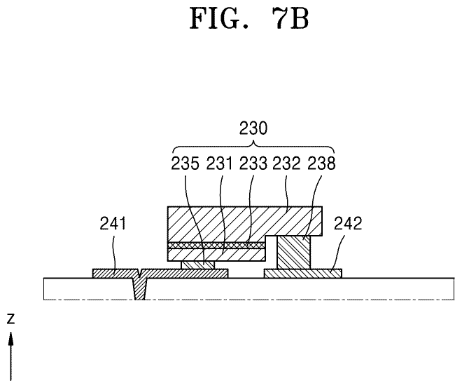

FIG. 7A is a schematic cross-sectional view of a light-emitting element of a display device according to one or more embodiments of the present disclosure.

Referring to FIG. 7A, the light-emitting element according to one or more embodiments of the present disclosure may include an organic light-emitting diode 220 including an organic material. The organic light-emitting diode 220 may include a first electrode 221 arranged on an insulating layer, a second electrode 225 facing the first electrode 221, and an emission layer 223 arranged between the first electrode 221 and the second electrode 225. A first functional layer 222 may be arranged between the first electrode 221 and the emission layer 223, and a second functional layer 224 may be arranged between the emission layer 223 and the second electrode 225.

An edge of the first electrode 221 may be covered with a bank layer BKL including an insulating material. The bank layer BKL may include an opening B-OP overlapping a central portion of the first electrode 221.

The first electrode 221 may include a conductive oxide, such as indium tin oxide (ITO), indium zinc oxide (IZO), zinc oxide (ZnO), indium oxide (In₂O₃), indium gallium oxide (IGO), and/or aluminum zinc oxide (AZO). In one or more embodiments, the first electrode 221 may include a reflective layer including silver (Ag), magnesium (Mg), aluminum (Al), platinum (Pt), palladium (Pd), gold (Au), nickel (Ni), neodymium (Nd), iridium (Ir), chromium (Cr), and/or a compound thereof. In one or more embodiments, the first electrode 221 may further include a layer including ITO, IZO, ZnO, and/or In₂O₃ above/below the reflective layer stated above.

The emission layer 223 may include a polymer organic material or a low-molecular-weight organic material, which emits light of a certain color. The first functional layer 222 may include a hole transport layer (HTL) and/or a hole injection layer (HIL). The second functional layer 224 may include an electron transport layer (ETL) and/or an electron injection layer (EIL).

The second electrode 225 may include a conductive material having a low work function. For example, the second electrode 225 may include a (semi)transparent layer including Ag, Mg, Al, Pt, Pd, Au, Ni, Nd, Ir, Cr, lithium (Li), calcium (Ca), alloys thereof, and/or the like. Alternatively, the second electrode 225 may further include a layer, such as ITO, IZO, ZnO, and/or In₂O₃, above the (semi)transparent layer including the above-stated material.

FIG. 7B is a schematic cross-sectional view of a light-emitting element of a display device according to one or more embodiments of the present disclosure.

Referring to FIG. 7B, the light-emitting element according to one or more embodiments of the present disclosure may include an inorganic light-emitting diode 230 including an inorganic material. The inorganic light-emitting diode 230 may include a first semiconductor layer 231, a second semiconductor layer 232, an intermediate layer 233 between the first semiconductor layer 231 and the second semiconductor layer 232, a first electrode 235 electrically connected to the first semiconductor layer 231, and a second electrode 238 electrically connected to the second semiconductor layer 232. The first electrode 235 and the second electrode 238 of the inorganic light-emitting diode 230 may respectively be electrically connected to a first electrode pad 241 and a second electrode pad 242, which are arranged on (e.g., at) the same layer.

In one or more embodiments, the first semiconductor layer 231 may include a p-type semiconductor layer. The p-type semiconductor layer is a semiconductor material with a composition formula of InₓAl_{y}Ga_{1-x-y}N (0≤x≤1, 0≤y≤1, 0≤x+y≤1), which may, for example, be selected from among GaN, AlN, AlGaN, InGaN, InN, InAlGaN, AlInN, and/or the like, and may be doped with a p-type dopant such as Mg, Zn, Ca, Sr, Ba, and/or the like.

The second semiconductor layer 232 may include, for example, an n-type semiconductor layer. The n-type semiconductor layer is a semiconductor material having a composition formula of InₓAl_{y}Ga_{1-x-y}N (0≤x≤1, 0≤y≤1, 0≤x+y≤1), which may, for example, be selected from among GaN, AlN, AlGaN, InGaN, InN, InAlGaN, AlInN, and/or the like, and may be doped with an n-type dopant such as Si, Ge, Sn, and/or the like.

The intermediate layer 233 is a region where electrons and holes are recombined, as the electrons and holes are recombined, the intermediate layer 233 may transition to a low energy level and generate light having a corresponding wavelength. For example, the intermediate layer 233 may be formed by including a semiconductor material having a composition formula of InₓAl_{y}Ga_{1-x-y}N (0≤x≤1, 0≤y≤1, 0≤x+y≤1), and may be formed as a single-quantum well structure or a multi-quantum well (MQW) structure. In addition, the intermediate layer 233 may also include a quantum wire structure or a quantum dot structure.

FIG. 7B shows that the first semiconductor layer 231 includes a p-type semiconductor layer, and the second semiconductor layer 232 includes an n-type semiconductor layer, but the present disclosure is not limited thereto. In one or more embodiments, the first semiconductor layer 231 may include an n-type semiconductor layer, and the second semiconductor layer 232 may include a p-type semiconductor layer.

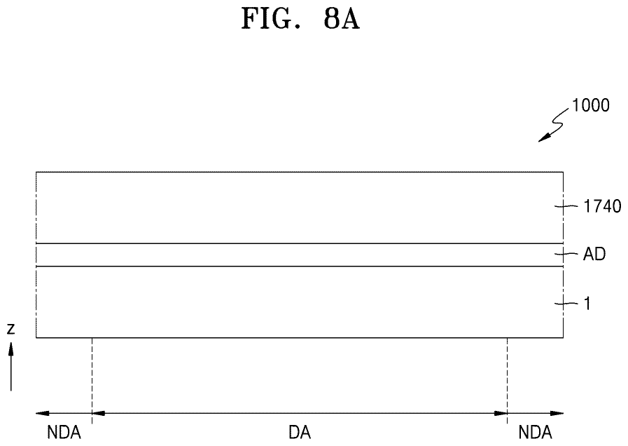

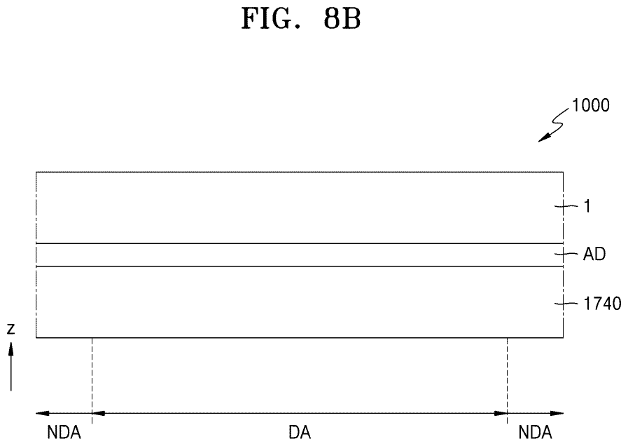

FIGS. 8A and 8B are schematic cross-sectional views of an electronic device 1000 according to one or more embodiments of the present disclosure.

Referring to FIGS. 8A and 8B, the electronic device 1000 may include the display device 1 and a strain sensor 1740.

The strain sensor 1740 may be attached to the display device 1 to measure the strain of the display device 1. The strain sensor 1740 may include layers, patterns, and/or lines of which a measurable physical quantity changes according to the stretching of the display device 1. For example, the strain sensor 1740 may include lines of which the resistance and/or capacitance changes due to stretching of the display device 1. In one or more embodiments, the strain sensor 1740 may include an optical layer or optical pattern of which the transmittance and/or reflectance changes due to stretching of the display device 1.

Based on the physical quantity according to the stretching of the display device 1, which is measured by the strain sensor 1740, the electronic device 1000 may improve the image quality of an image implemented by the display device 1 or control the display device 1. A control operation of the display device 1 may include, for example, an operation of displaying an operation image to protect the display device 1, an operation of cutting off a voltage for driving the display device 1, or an operation of stopping a stretching operation of the display device 1.

For example, as shown in FIG. 8A, the strain sensor 1740 may be attached to the front surface of the display device 1. That is, the strain sensor 1740 may be attached to a surface of the display device 1, the surface being far away from the substrate 100 (refer to FIG. 5). However, this is an example, and the arrangements of the display device 1 and the strain sensor 1740 are not limited thereto. For example, as shown in FIG. 8B, the strain sensor 1740 may be attached to the rear surface of the display device 1. That is, the strain sensor 1740 may be attached to a surface of the display device 1, the surface being close to the substrate 100 (refer to FIG. 5). An adhesive AD may be arranged between the display device 1 and the strain sensor 1740. The adhesive AD may fix the display device 1 and the strain sensor 1740.

The electronic device 1000 may include the display area DA and the non-display area NDA. As described above, the display area DA may be an area overlapping an area that provides certain images by using light emitted by pixels of the display device 1, and the non-display area NDA may be an area in which the pixels of the display device 1 are not arranged and surrounding the display area DA. That is, each of the display device 1 and the strain sensor 1740 may include the display area DA and the non-display area NDA.

In one or more embodiments, the strain sensor 1740 may be attached to the display device 1 from the outside of the display device 1, instead of having the strain sensor 1740 built into the display device 1. Accordingly, the quality of the display device 1, such as resolution and durability, may be improved, and a ratio of the area of the non-display area NDA to the area of the display area DA may decrease.

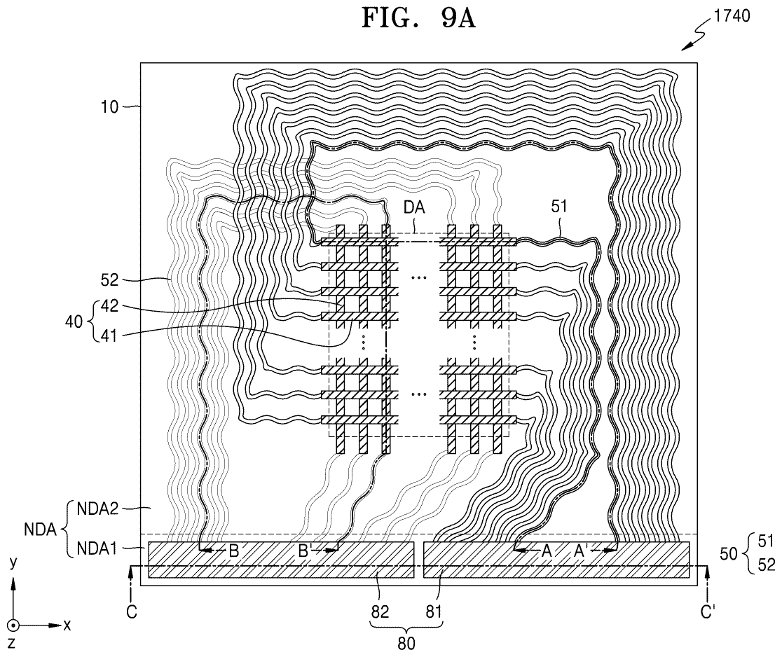

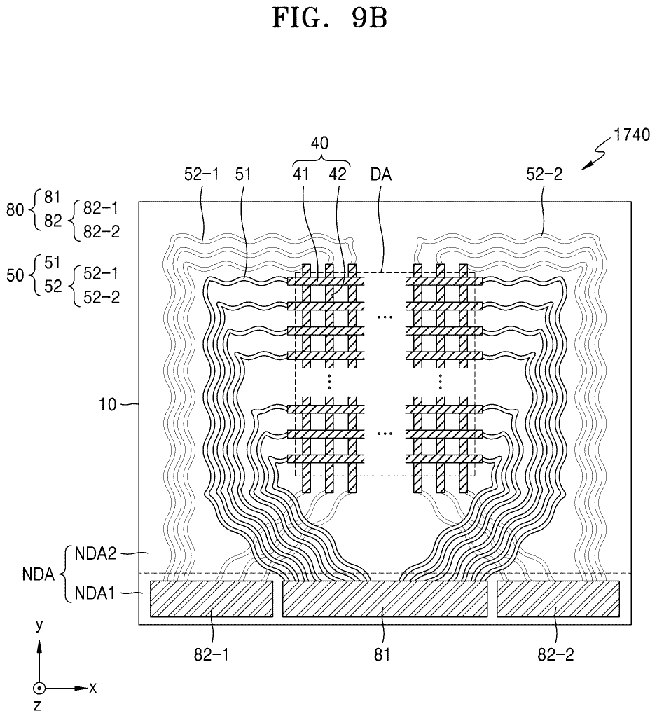

FIGS. 9A and 9B are schematic plan views of the strain sensor 1740 according to one or more embodiments of the present disclosure.

Referring to FIGS. 9A and 9B, the strain sensor 1740 may include a first support layer 10, a sensor line portion 40, a connection line portion 50, and a circuit board portion 80.

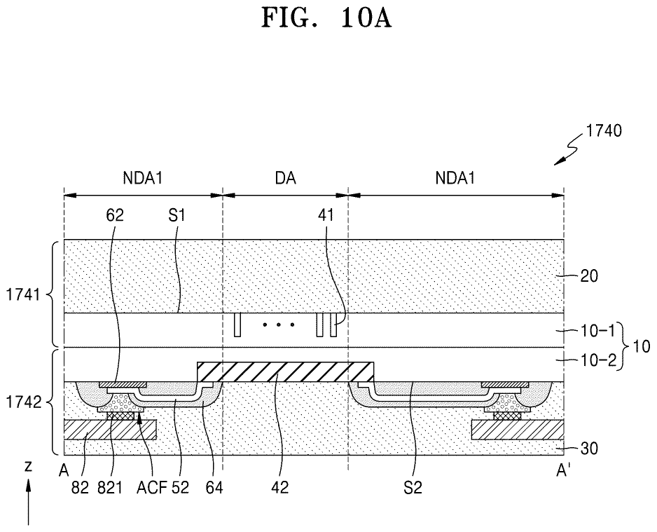

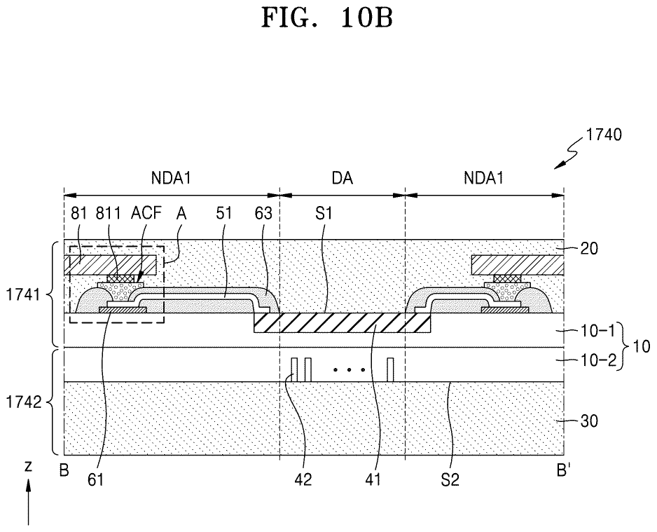

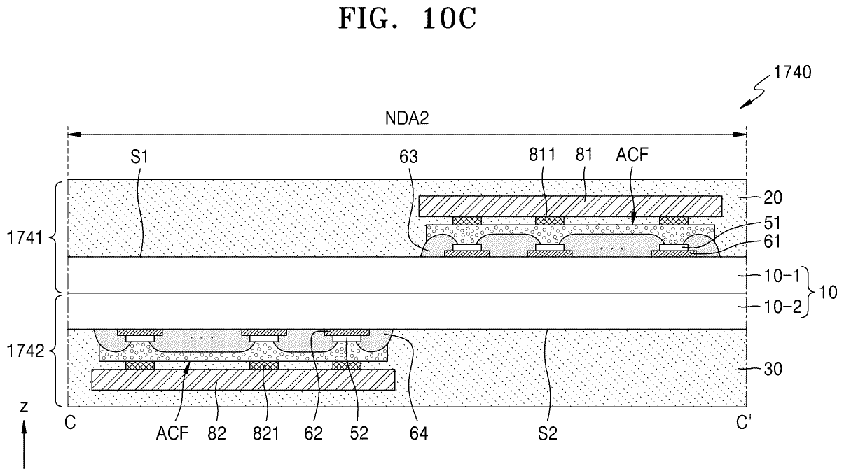

The first support layer 10 may support the sensor line portion 40, the connection line portion 50, and the circuit board portion 80. A detailed description of the first support layer 10 is given below with reference to FIGS. 10A-10C.

The sensor line portion 40 may be arranged in the display area DA and include a plurality of first sensor lines 41 and a plurality of second sensor lines 42.

The plurality of first sensor lines 41 may extend in the first direction (e.g., the x direction and/or the −x direction) and may be spaced (e.g., spaced apart) from each other in the second direction (e.g., the y direction and/or the −y direction). The plurality of first sensor lines 41 may have straight-line shapes. The plurality of second sensor lines 42 may extend in the second direction (e.g., the y direction and/or the −y direction) and may be spaced (e.g., spaced apart) from each other in the first direction (e.g., the x direction and/or the −x direction). The plurality of second sensor lines 42 may have straight-line shapes.

The plurality of first sensor lines 41 and the plurality of second sensor lines 42 may cross each other in the display area DA. In a plan view, the plurality of first sensor lines 41 and the plurality of second sensor lines 42 may overlap each other. In a plan view, the plurality of first sensor lines 41 and the plurality of second sensor lines 42 may be arranged in a grid shape.

For example, the plurality of first sensor lines 41 may be arranged on the plurality of second sensor lines 42. Alternatively, for example, the plurality of second sensor lines 42 may be arranged on the plurality of first sensor lines 41. Hereinafter, the descriptions is given on the assumption that the plurality of first sensor lines 41 are arranged on the plurality of second sensor lines 42.

The non-display area NDA may include the first non-display area NDA1 and the second non-display area NDA2. The second non-display area NDA2 may be arranged to be around (e.g., surround) the display area DA. The first non-display area NDA1 may be arranged on one side of the second non-display area NDA2. The first non-display area NDA1 may be spaced (e.g., spaced apart) from the display area DA. The second non-display area NDA2 may be in contact with each of the first non-display area NDA1 and the display area DA.

The circuit board portion 80 may be arranged in the non-display area NDA. The circuit board portion 80 may include a first circuit board 81 and a second circuit board 82, which are arranged in the first non-display area NDA1 to be spaced (e.g., spaced apart) from each other. The first circuit board 81 and the second circuit board 82 may be spaced (e.g., spaced apart) from each other in the first direction (e.g., the x direction and/or the −x direction).

The connection line portion 50 may be arranged in the non-display area NDA and include a plurality of first connection lines 51 and a plurality of second connection lines 52.

The plurality of first connection lines 51 may electrically connect the plurality of first sensor lines 41 to the first circuit board 81, respectively. One corresponding first sensor line 41 may be connected to one first connection line 51. One side of the plurality of first connection lines 51 may be connected to the plurality of first sensor lines 41 corresponding thereto, and the other side of the plurality of first connection lines 51 may be connected to the first circuit board 81. At least some of the plurality of first connection lines 51 may be arranged in the second non-display area NDA2. The plurality of first connection lines 51 may have serpentine shapes.

However, this is an example, and the arrangement and shape of the plurality of first connection lines 51 are not limited thereto. For example, unlike that shown in FIGS. 9A and 9B, the plurality of first sensor lines 41 may be connected to one first connection line 51. For example, unlike that shown in FIGS. 9A and 9B, the plurality of first connection lines 51 may be connected to one first sensor line 41. For example, the plurality of first connection lines 51 may have straight-line shapes. The arrangement and shape of the plurality of first connection lines 51 may be designed in various ways according to requirements.

The plurality of second connection lines 52 may electrically connect the plurality of second sensor lines 42 to the second circuit board 82, respectively. One corresponding second sensor line 42 may be connected to one second connection line 52. One side of the plurality of second connection lines 52 may be connected to the plurality of second sensor lines 42 corresponding thereto, and the other side of the plurality of second connection lines 52 may be connected to the second circuit board 82. At least some of the plurality of second connection lines 52 may be arranged in the second non-display area NDA2. The plurality of second connection lines 52 may have serpentine shapes.

However, this is an example, and the arrangement and shape of the plurality of second connection lines 52 are not limited thereto. For example, unlike that shown in FIGS. 9A and 9B, the plurality of second sensor lines 42 may be connected to one second connection line 52. For example, unlike that shown in FIGS. 9A and 9B, the plurality of second connection lines 52 may be connected to one second sensor line 42. For example, the plurality of second connection lines 52 may have straight-line shapes. The arrangement and shape of the plurality of second connection lines 52 may be designed in various ways according to requirements.

The plurality of first connection lines 51 and the plurality of second connection lines 52 may cross each other in the second non-display area NDA2. In a plan view, the plurality of first connection lines 51 and the plurality of second connection lines 52 may overlap each other.

At least two of the plurality of first connection lines 51 may have different lengths. The plurality of first connection lines 51 may have a shorter length as a distance from the first circuit board 81 decreases and may have a longer length as the distance from the first circuit board 81 increases. At least two of the plurality of first connection lines 51 may have different cross-sectional areas from one another. The cross-sectional area of the plurality of first connection lines 51 may increase as the length thereof increases. Accordingly, the resistance deviation due to the difference in length of the plurality of first connection lines 51 may be reduced.

At least two of the plurality of second connection lines 52 may have different lengths. The plurality of second connection lines 52 may have a shorter length as a distance from the second circuit board 82 decreases and may have a longer length as the distance from the second circuit board 82 increases. At least two of the plurality of second connection lines 52 may have different cross-sectional areas from one another. The cross-sectional area of the plurality of second connection lines 52 may increase as the length thereof increases. Accordingly, the resistance deviation due to the difference in length of the plurality of second connection lines 52 may be reduced.

Referring to FIG. 9A, one first circuit board 81 and one second circuit board 82 may be provided. The plurality of first connection lines 51 connected to one side and the other side of each of the plurality of first sensor lines 41 may each be connected to the first circuit board 81. The plurality of second connection lines 52 connected to one side and the other side of each of the plurality of second sensor lines 42 may each be connected to the second circuit board 82.

Referring to FIG. 9B, the second circuit board 82 may include a second-1 circuit board 82-1 and a second-2 circuit board 82-2. That is, two second circuit boards 82 may be provided. The first circuit board 81 may be arranged between the second-1 circuit board 82-1 and the second-2 circuit board 82-2. In a plan view, the second-1 circuit board 82-1, the first circuit board 81, and the second-2 circuit board 82-2 may be sequentially arranged along the first direction (e.g., the x direction and/or the −x direction).

The plurality of second connection lines 52 may include a plurality of second-1 connection lines 52-1 and a plurality of second-2 connection lines 52-2. The plurality of second-1 connection lines 52-1 may electrically connect some of the plurality of second sensor lines 42 to the second-1 circuit board 82-1. The plurality of second-2 connection lines 52-2 may connect the remaining second sensor lines 42 to the second-2 circuit board 82-2.

The plurality of first connection lines 51 connected to one side and the other side of each of the plurality of first sensor lines 41 may each be connected to the first circuit board 81. The plurality of second-1 connection lines 52-1 connected to one side and the other side of some of the plurality of second sensor lines 42 may each be connected to the second-1 circuit board 82-1. The plurality of second-2 connection lines 52-2 connected to one side and the other side of the remaining second sensor lines 42 may be connected to the second-2 circuit board 82-2.

The numbers and arrangements of the circuit board portions 80 and the connection line portions 50 described with reference to FIGS. 9A and 9B are examples and are not limited thereto. For example, four or more circuit board portions 80 may also be provided.

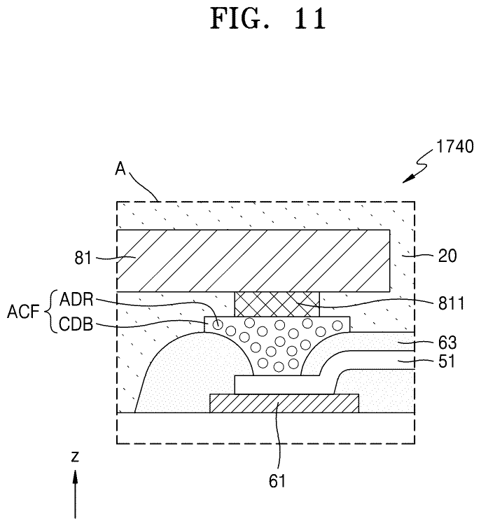

FIGS. 10A-10C are schematic cross-sectional views of the strain sensor 1740 according to one or more embodiments of the present disclosure, and FIG. 11 is a schematic cross-sectional view of the strain sensor 1740 according to one or more embodiments of the present disclosure.

In particular, FIG. 10A is a cross-sectional view of the strain sensor 1740 taken along the line A-A′ of FIG. 9A, FIG. 10B is a cross-sectional view of the strain sensor 1740 taken along the line B-B′ of FIG. 9A, FIG. 10C is a cross-sectional view of the strain sensor 1740 taken along the line C-C′ of FIG. 9A, and FIG. 11 is an enlarged view of a region A of FIG. 10B of the strain sensor 1740.

Referring to FIGS. 9A-11 , the strain sensor 1740 may include a first sensor module 1741 and a second sensor module 1742.

The first support layer 10 may have a first support surface S1 and a second support surface S2 opposite to the first support surface S1. The first support layer 10 may include a dielectric elastomer. The first support layer 10 may include at least one of an acrylic polymer, a urethane polymer, and/or a silicone polymer. The first support layer 10 may include a first-1 support layer 10-1 and a first-2 support layer 10-2. The first-1 support layer 10-1 may be arranged on the first-2 support layer 10-2. At this time, the first-1 support layer 10-1 may have the first support surface S1 described above, and the first-2 support layer 10-2 may have the second support surface S2 described above. For example, the first-1 support layer 10-1 and the first-2 support layer 10-2 may include the same material.

The first sensor module 1741 may include the first-1 support layer 10-1, the plurality of first sensor lines 41, the plurality of first connection lines 51, a first inorganic layer 61, a first organic layer 63, and the first circuit board 81.

The first-1 support layer 10-1 may support the plurality of first sensor lines 41, the plurality of first connection lines 51, a plurality of first inorganic layers 61, a plurality of first organic layers 63, and the first circuit board 81. The plurality of first sensor lines 41 may be accommodated in the first-1 support layer 10-1. One surface of the plurality of first sensor lines 41 may form the same plane as the first support surface S1 of the first-1 support layer 10-1. The plurality of first connection lines 51 may be arranged on the first support surface S1. The plurality of first connection lines 51 may be in contact with the plurality of first sensor lines 41, respectively.

The plurality of first sensor lines 41 may include a material having both excellent stretchability and electrical characteristics. For example, the plurality of first sensor lines 41 may include liquid metal. For example, the plurality of first sensor lines 41 may include a metal nanostructure and an elastic polymer. For example, the plurality of first sensor lines 41 may include a conductive composite material including an elastomer.

For example, when the plurality of first connection lines 51 have serpentine shapes, the plurality of first connection lines 51 may include a conductive material including Mo, Al, Cu, Ti, and/or the like, and may include a multi-layer or a single layer, each including the above material. For example, the plurality of first connection lines 51 may include a metal thin film including a triple layer of a Ti/Al/Ti structure.

For example, when the plurality of first connection lines 51 have straight-line shapes, the plurality of first connection lines 51 may include the same material as the first sensor line 41. For example, the plurality of first connection lines 51 may include at least one of a liquid metal, a metal nanostructure, an elastic polymer, and/or a conductive composite material including an elastomer.

The plurality of first inorganic layers 61 may be arranged between the first support layer 10 (particularly the first-1 support layer 10-1) and the plurality of first connection lines 51. The plurality of first inorganic layers 61 may be arranged on the first support surface S1. The plurality of first inorganic layers 61 may be spaced (e.g., spaced apart) from each other. One of the plurality of first connection lines 51 may correspond to one of the plurality of first inorganic layers 61.

The plurality of first inorganic layers 61 may include an inorganic insulating material including silicon oxide, silicon nitride, nitrogen oxide, silicon oxynitride, aluminum oxide, titanium oxide, and/or the like, or may include a multi-layer or a single layer, each including the above material.

The plurality of first organic layers 63 may be arranged on the first support surface S1 to cover the plurality of first connection lines 51, respectively. The plurality of first organic layers 63 may cover the plurality of first inorganic layers 61. The plurality of first organic layers 63 may be in contact with the first-1 support layer 10-1 and the plurality of first sensor lines 41. Openings may be formed in the plurality of first organic layers 63, and the openings of the plurality of first organic layers 63 may expose the plurality of first connection lines 51. The plurality of first organic layers 63 may include an organic insulating material, such as polyimide.

The first circuit board 81 may be arranged on the first support surface S1. A plurality of first connection portions 811 may electrically connect the plurality of first connection lines 51 to the first circuit board 81, respectively. At this time, the plurality of first inorganic layers 61 may overlap the plurality of first connection portions 811 in a thickness direction (e.g., z direction) of the support layer 10.

In one or more embodiments, a first connection portion 811 may be electrically connected to the first connection line 51 through an anisotropic conductive film ACF. For example, even when the first connection line 51 is not in direct contact with the first connection portion 811, the first connection line 51 may be physically and/or electrically connected to the first connection portion 811 through the anisotropic conductive film ACF.

The anisotropic conductive film ACF may include an adhesive resin ADR and a plurality of conductive balls CDB distributed in the adhesive resin ADR. The adhesive resin ADR may fix the plurality of conductive balls CDB in a certain area and physically connect the first connection line 51 to the first connection portion 811. The plurality of conductive balls CDB may electrically connect the first connection line 51 to the first connection portion 811.

The first sensor module 1741 may further include a first elastomer layer 20. The first elastomer layer 20 may be arranged on the first support surface S1 to cover the first-1 support layer 10-1, the first sensor line 41, the first organic layer 63, and the first circuit board 81.

The first elastomer layer 20 may absorb stress that may occur when the display device 1 (refer to FIG. 8A) is stretched. The first elastomer layer 20 may include an elastic polymer. For example, the first elastomer layer 20 may include thermoplastic polyurethane, silicone, thermoplastic rubbers, elastolefin, thermoplastic olefin, polyamide, polyether block amide, synthetic polyisoprene, polybutadiene, chloroprene rubber, butyl rubber, styrene-butadiene, epichlorohydrin rubber, polyacrylic rubber, silicone rubber, fluorosilicone rubber, fluoroelastomers, ethylene-vinyl acetate, polydimethylsiloxane (PDMS), and/or ecoflex.

The second sensor module 1742 may include the first-2 support layer 10-2, the plurality of second sensor lines 42, the plurality of second connection lines 52, a second inorganic layer 62, a second organic layer 64, and the second circuit board 82.

The first-2 support layer 10-2 may support the plurality of second sensor lines 42, the plurality of second connection lines 52, a plurality of second inorganic layers 62, a plurality of second organic layers 64, and the second circuit board 82. The plurality of second sensor lines 42 may be accommodated in the first-2 support layer 10-2. One surface of the plurality of second sensor lines 42 may form the same plane as the second support surface S2 of the first-2 support layer 10-2. The plurality of second connection lines 52 may be arranged on the second support surface S2. The plurality of second connection lines 52 may be in contact with the plurality of second sensor lines 42, respectively.

The plurality of second sensor lines 42 may include a material having both excellent stretchability and electrical characteristics. The plurality of second sensor lines 42 may include the same material as the plurality of first sensor lines 41. The plurality of second connection lines 52 may include a conductive material. The plurality of second connection lines 52 may include the same material as the plurality of first connection lines 51.

The plurality of second inorganic layers 62 may be arranged between the first support layer 10 (particularly the first-2 support layer 10-2) and the plurality of second connection lines 52. The plurality of second inorganic layers 62 may be arranged on the second support surface S2. The plurality of second inorganic layers 62 may be spaced (e.g., spaced apart) from each other. One of the plurality of second connection lines 52 may correspond to one of the plurality of second inorganic layers 62. The plurality of second inorganic layers 62 may include the same material as the plurality of first inorganic layers 61.

The plurality of second organic layers 64 may be arranged on the second support surface S2 to cover the plurality of second connection lines 52, respectively. The plurality of second organic layers 64 may cover the plurality of second inorganic layers 62. The plurality of second organic layers 64 may be in contact with the first-2 support layer 10-2 and the plurality of second sensor lines 42. Openings may be formed in the plurality of second organic layers 64, and the openings of the plurality of second organic layers 64 may expose the plurality of second connection lines 52. The plurality of second organic layers 64 may include the same material as the plurality of first organic layers 63.

The second circuit board 82 may be arranged on the second support surface S2. A plurality of second connection portions 821 may electrically connect the plurality of second connection lines 52 to the second circuit board 82, respectively. At this time, the plurality of second inorganic layers 62 may overlap the plurality of second connection portions 821 in the thickness direction (e.g., z direction) of the support layer 10.

In one or more embodiments, a second connection portion 821 may be electrically connected to the second connection line 52 through an anisotropic conductive film ACF. For example, even when the second connection line 52 is not in direct contact with the second connection portion 821, the second connection line 52 may be physically and/or electrically connected to the second connection portion 821 through the anisotropic conductive film ACF.

The second sensor module 1742 may further include a second elastomer layer 30. The second elastomer layer 30 may be arranged on the second support surface S2 to cover the first-2 support layer 10-2, the second sensor line 42, the second organic layer 64, and the second circuit board 82. The second elastomer layer 30 may include the same material as the first elastomer layer 20.

The first sensor module 1741 and the second sensor module 1742 may be attached to each other. In particular, the first-1 support layer 10-1 and the first-2 support layer 10-2 may be attached to each other. In this structure, the plurality of first sensor lines 41 and the plurality of second sensor lines 42 may be arranged to face each other. In addition, the first circuit board 81 and the second circuit board 82 may be arranged to face in directions away from each other. In addition, in a cross-sectional view, the plurality of first sensor lines 41 and the plurality of second sensor lines 42 may be spaced (e.g., spaced apart) from each other. Also, in a cross-sectional view, the plurality of first connection lines 51 and the plurality of second connection lines 52 may be spaced (e.g., spaced apart) from each other.

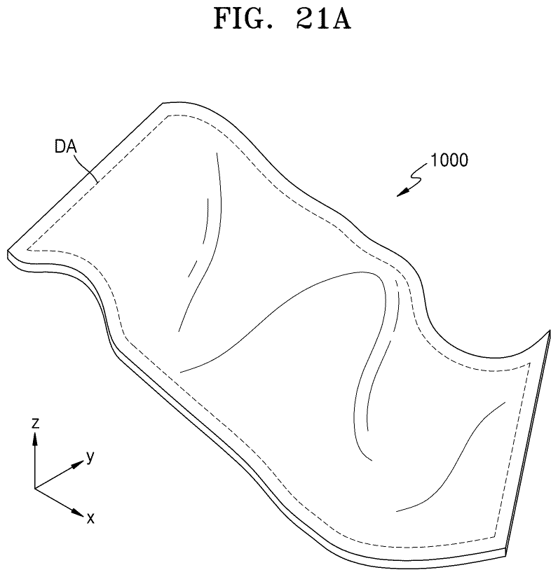

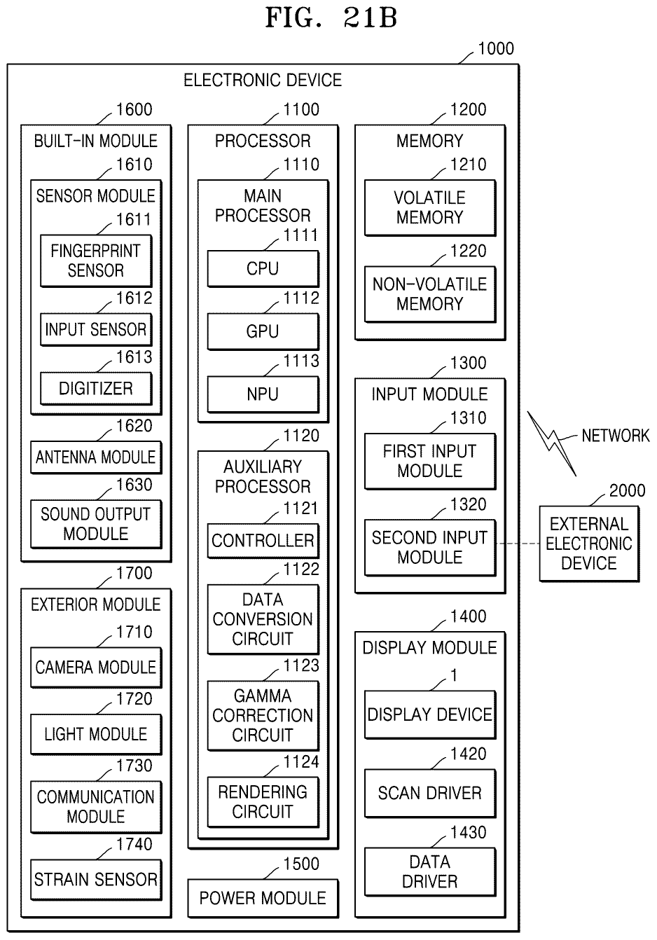

The resistance of the sensor line portion 40 including the plurality of first sensor lines 41 and the plurality of second sensor lines 42 may be changed as the display device 1 (refer to FIG. 8A) is stretched. The connection line portion 50 including the plurality of first connection lines 51 and the plurality of second connection lines 52 may transmit a change in resistance sensed in the sensor line portion 40 to the circuit board portion 80. The circuit board portion 80 may be connected to a processor 1100 (refer to FIG. 21B) and receive driving signals to drive the strain sensor 1740 or provide a change in resistance of the sensor line portion 40, which is received from the connection line portion 50, to the processor 1100 (refer to FIG. 21B).

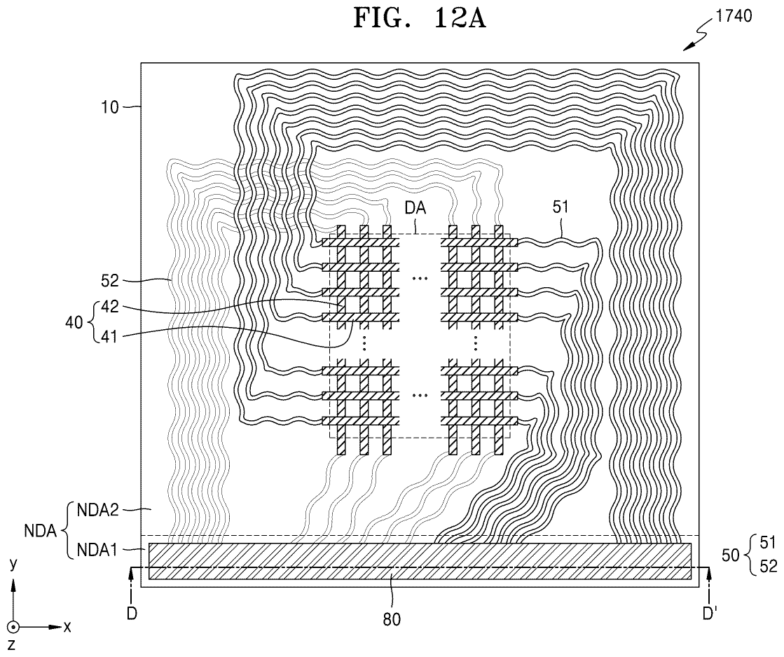

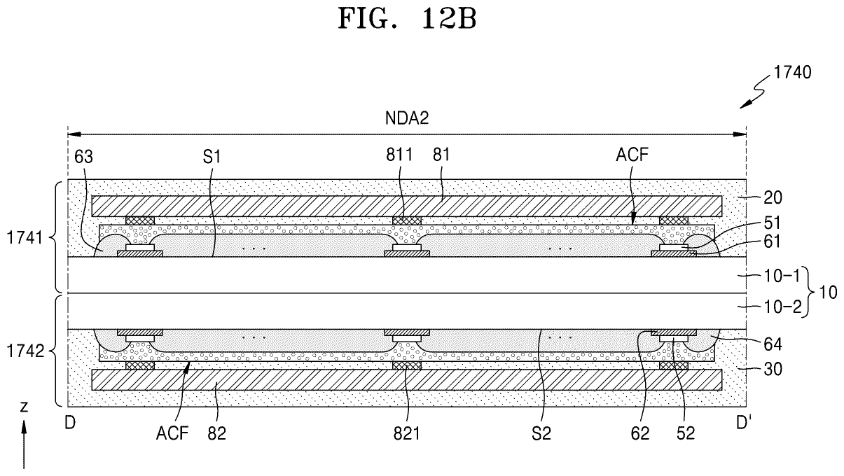

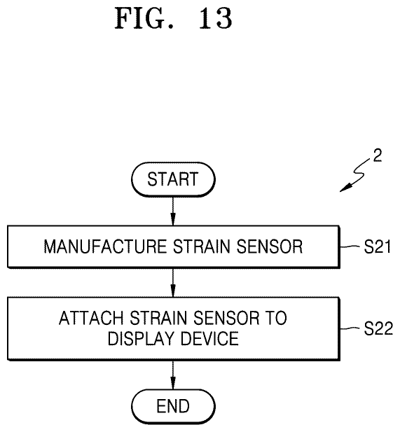

FIG. 12A is a schematic plan view of the strain sensor 1740 according to one or more embodiments of the present disclosure, and FIG. 12B is a schematic cross-sectional view of the strain sensor 1740 according to one or more embodiments of the disclosure.

In particular, FIG. 12B is a cross-sectional view of the strain sensor 1740 taken along the line D-D′ of FIG. 12A.

In FIGS. 12A and 12B, the same reference numerals as those in FIGS. 9A-11 refer to the same members, and redundant descriptions thereof are omitted.

Referring to FIGS. 12A-12B , the strain sensor 1740 may include the first support layer 10, the sensor line portion 40, the connection line portion 50, the first inorganic layer 61, the second inorganic layer 62, the first organic layer 63, the second organic layer 64, and the circuit board portion 80.

The first support layer 10 may have the first support surface S1 and the second support surface S2 opposite to the first support surface S1. The first support layer 10 may include the first-1 support layer 10-1 and the first-2 support layer 10-2. The first-1 support layer 10-1 may be arranged on the first-2 support layer 10-2. At this time, the first-1 support layer 10-1 may have the first support surface S1 described above, and the first-2 support layer 10-2 may have the second support surface S2 described above.

The first-1 support layer 10-1 may support the plurality of first sensor lines 41, the plurality of first connection lines 51, the plurality of first inorganic layers 61, the plurality of first organic layers 63, and the first circuit board 81. The first-2 support layer 10-2 may support the plurality of second sensor lines 42, the plurality of second connection lines 52, the plurality of second inorganic layers 62, the plurality of second organic layers 64, and the second circuit board 82.

The circuit board portion 80 may be arranged in the non-display area NDA. The circuit board portion 80 may include the first circuit board 81 and the second circuit board 82, which are arranged in the first non-display area NDA1 to be spaced (e.g., spaced apart) from each other.

The first circuit board 81 may be arranged on the first support surface S1. The plurality of first connection portions 811 may electrically connect the plurality of first connection lines 51 to the first circuit board 81, respectively. The second circuit board 82 may be arranged on the second support surface S2. The plurality of second connection portions 821 may electrically connect the plurality of second connection lines 52 to the second circuit board 82, respectively.

In a plan view, the first circuit board 81 and the second circuit board 82 may overlap each other in the thickness direction (e.g., z direction) of the support layer 10. For example, as shown in FIG. 12A, when viewed from an upper portion of the strain sensor 1740, the second circuit board 82 may be covered by the first circuit board 81. However, unlike shown in FIG. 12A, when only a portion of the second circuit board 82 overlaps the first circuit board 81, the remaining portion of the second circuit board 82 may be seen when viewed from the upper portion of the strain sensor 1740. However, as shown in FIG. 12B, in a cross-sectional view, the first circuit board 81 and the second circuit board 82 may be spaced (e.g., spaced apart) from each other with the first support layer 10 between the first circuit board 81 and the second circuit board 82.

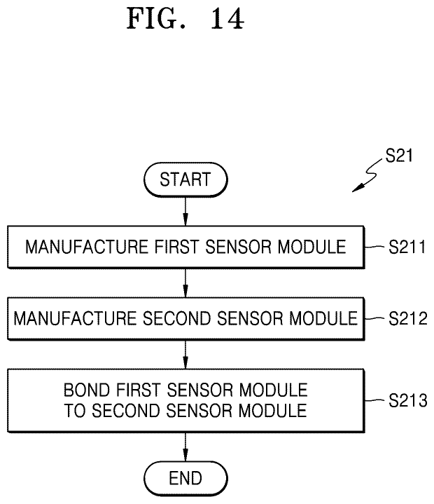

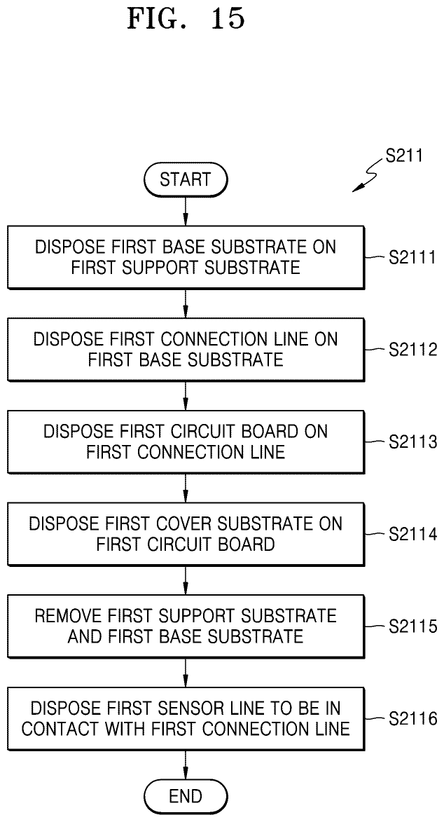

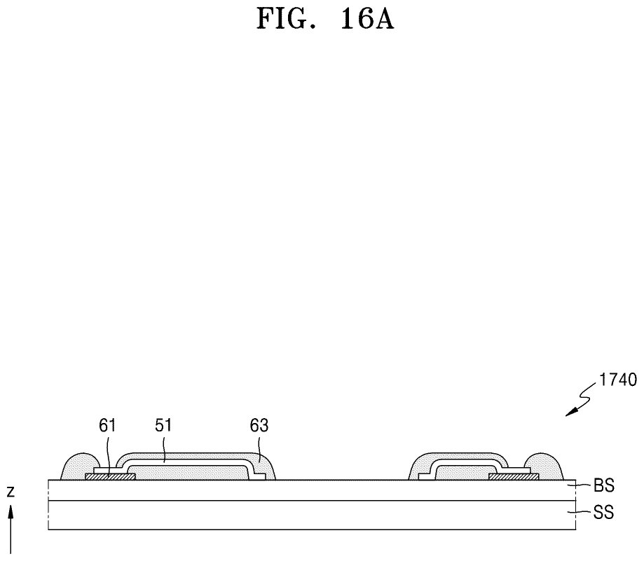

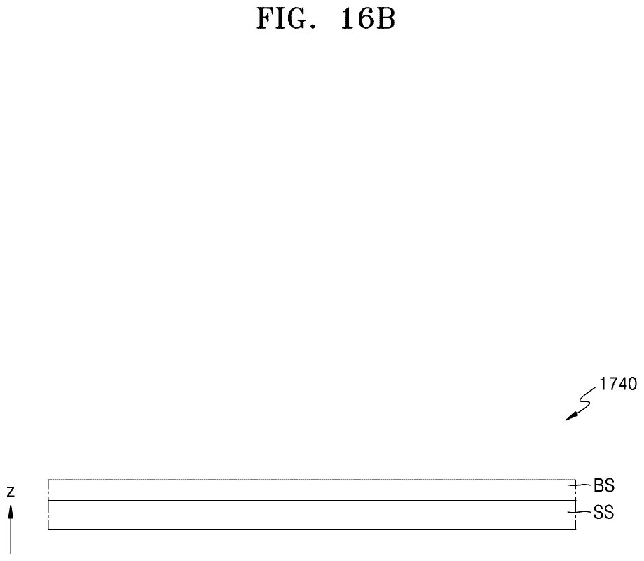

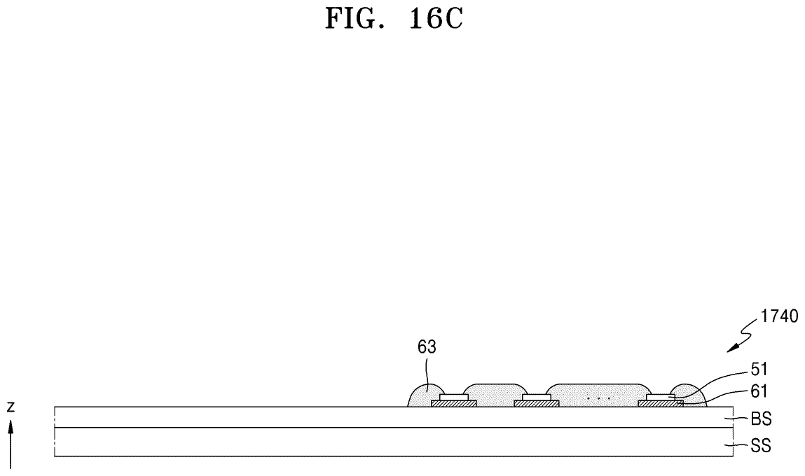

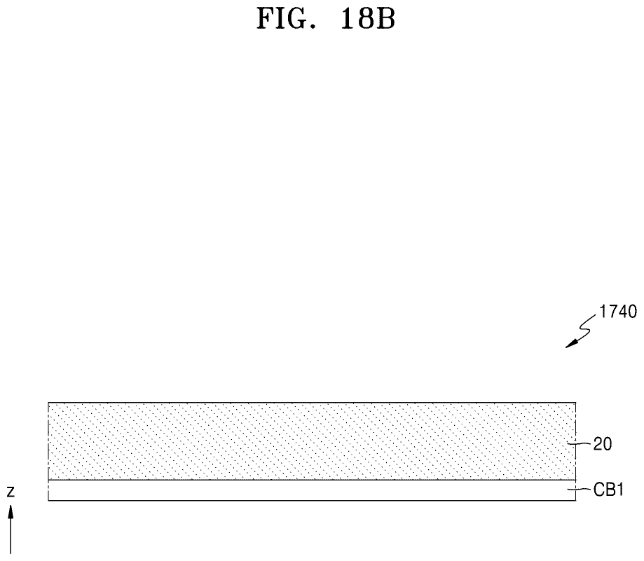

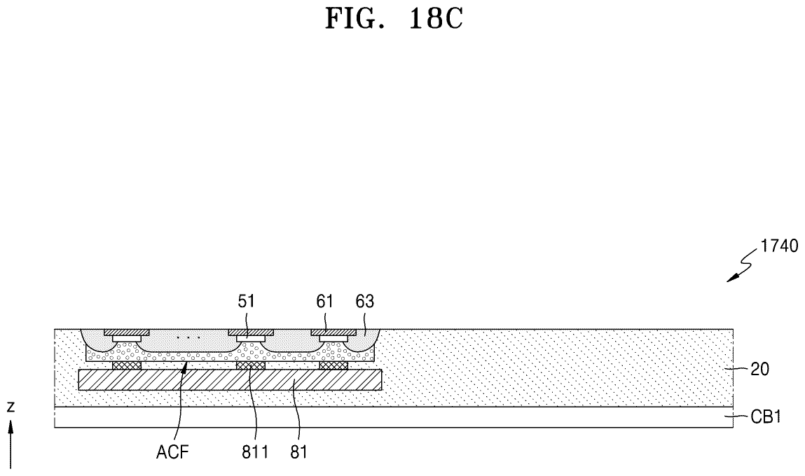

FIG. 13 is a flowchart schematically illustrating a method 2 of manufacturing an electronic device according to one or more embodiments of the present disclosure, FIG. 14 is a flowchart schematically illustrating operation S21 of manufacturing the strain sensor 1740 (refer to FIG. 10A) according to one or more embodiments of the present disclosure, FIG. 15 is a flowchart schematically illustrating operation S211 of manufacturing the first sensor module 1741 (refer to FIG. 10A) according to one or more embodiments of the present disclosure, and FIGS. 16A-20C are schematic cross-sectional views of the strain sensor 1740 (refer to FIG. 10A) according to one or more embodiments of the present disclosure.

In particular, FIGS. 16A, 17A, 18A, 19A, and 20A are cross-sectional views of the strain sensor 1740 taken along the line A-A of FIG. 9A, FIGS. 16B, 17B, 18B, 19B, and 20B are cross-sectional views of the strain sensor 1740 taken along the line B-B of FIG. 9A, and FIGS. 16C, 17C, 18C, 19C, and 20C are cross-sectional views of the strain sensor 1740 taken along the line C-C′ of FIG. 9A.

Referring to FIGS. 13-20C , the method 2 of manufacturing an electronic device is described.

Referring to FIG. 13, the method 2 of manufacturing an electronic device may include operation S21 of manufacturing the strain sensor 1740 (refer to FIG. 10A) and operation S22 of attaching the strain sensor 1740 to the display device 1 (refer to FIG. 8A).

Referring to FIG. 14, operation S21 of manufacturing the strain sensor 1740 (refer to 10A) may include operation S211 of manufacturing the first sensor module 1741 (refer to FIG. 10A), operation S212 of manufacturing the second sensor module 1742 (refer to FIG. 10A), and operation S213 of bonding the first sensor module 1741 (refer to FIG. 10A) to the second sensor module 1742 (refer to FIG. 10A).

First, referring to FIGS. 15-16C , operation S211 of manufacturing the first sensor module 1741 (refer to FIG. 10A) may include operation S2111 of arranging a first base substrate BS on a first support substrate SS, and operation S2112 of arranging the first connection line 51 on the first base substrate BS.

The first support substrate SS may be a rigid substrate. For example, the first support substrate SS may be a transparent substrate containing SiO₂ as a main component, or a substrate including a polymer resin such as reinforced plastic.

The first base substrate BS may cover the first support substrate SS. The first base substrate BS may include a polymer resin. For example, the first base substrate BS may include polyethersulfone, polyacrylate, polyetherimide, polyethylene naphthalate, polyethylene terephthalate, polyphenylene sulfide, polyarylate, polyimide, polycarbonate, cellulose acetate propionate, and/or the like.

The first connection line 51 may be arranged on the first base substrate BS. The first inorganic layer 61 may be arranged between the first connection line 51 and the first base substrate BS. The first organic layer 63 may be arranged on the first base substrate BS and cover at least a portion of the first connection line 51. A portion of the first connection line 51 may be exposed to the outside through an opening formed in the first organic layer 63.

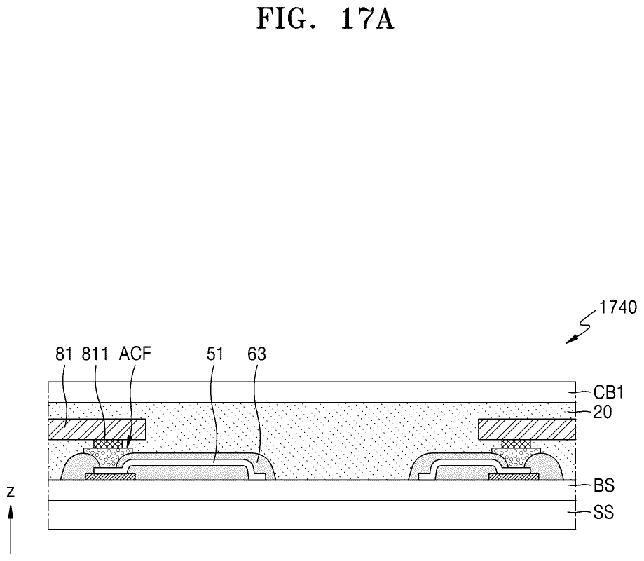

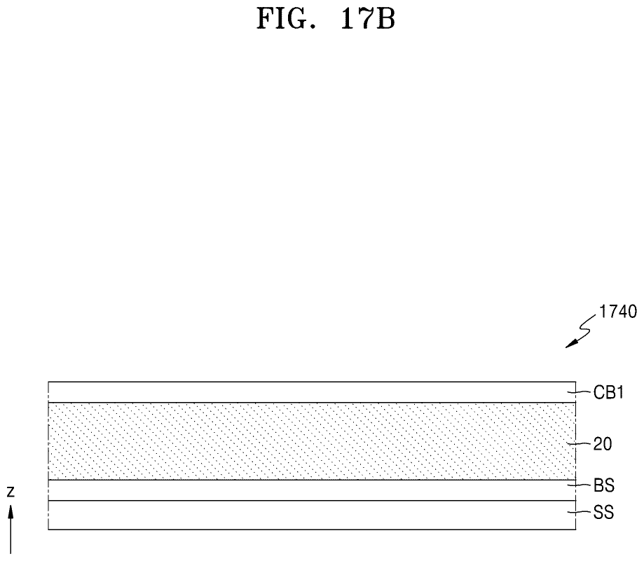

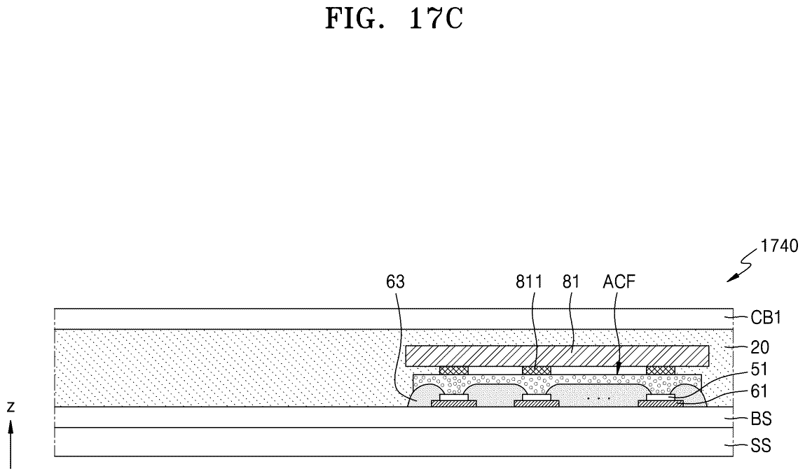

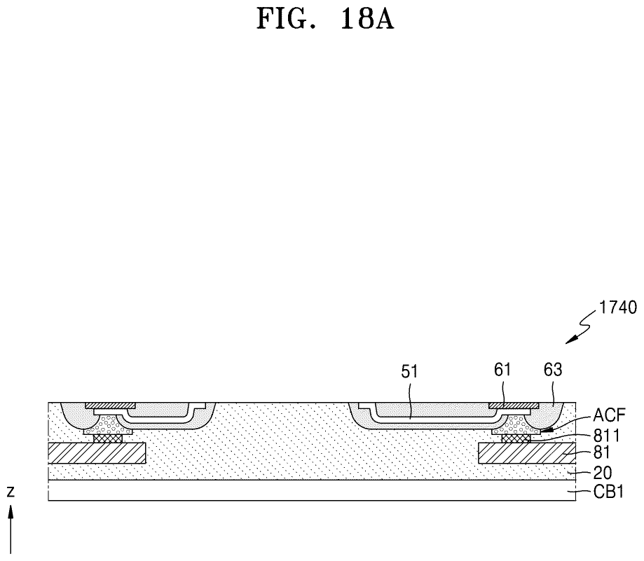

Referring to FIGS. 15 and 17A-17C, operation S211 of manufacturing the first sensor module 1741 may include operating S2113 of arranging the first circuit board 81 on the first connection line 51, and operation S2114 of arranging a first cover substrate CB1 on the first circuit board 81.

The first circuit board 81 may be connected to the first connection line 51 through the first connection portion 811. At this time, the anisotropic conductive film ACF may be arranged between the first connection portion 811 and the first connection line 51. Because the first inorganic layer 61 is positioned to overlap the first connection portion 811, in operation S2113 of arranging the first circuit board 81 on the first connection line 51, the first inorganic layer 61 may stably support the first connection portion 811.

The first elastomer layer 20 may be formed to cover the first circuit board 81, the first organic layer 63, and the first base substrate BS. The first elastomer layer 20 may function as a planarization layer. The first elastomer layer 20 may be formed through a thermal curing process after a material forming the first elastomer layer 20 is deposited. In the thermal curing process, the first elastomer layer 20 may be heated at 80° C. or higher for 30 minutes to 2 hours. However, the present disclosure is not limited thereto, and the first elastomer layer 20 may also be cured through an ultraviolet (UV) curing process.

The first cover substrate CB1 may be formed on the first elastomer layer 20. The first cover substrate CB1 may be attached to an upper surface of the first elastomer layer 20 through an adhesive layer between the first elastomer layer 20 and the first cover substrate CB1. The first cover substrate CB1 may be a protective film that may prevent scratches or marks from occurring on the first sensor module 1741 during a process. For example, the first cover substrate CB1 may include an insulating film. However, this is an example, and a method of attaching the first cover substrate CB1 may be varied.

Referring to FIGS. 15 and 17A-18C, operation S211 of manufacturing the first sensor module 1741 (refer to FIG. 10A) may include operation S2115 of removing the first support substrate SS and the first base substrate BS.

The first support substrate SS may be removed from the first base substrate BS. A coupling force between the first support substrate SS and the first base substrate BS may be weakened by irradiating a laser beam to a surface of the first support substrate SS, which is opposite to one surface of the first support substrate SS in contact with the first base substrate BS. Accordingly, the first support substrate SS may be peeled off from the first base substrate BS. However, this is an example, and a method of removing the first support substrate SS may be varied.

The first base substrate BS may be entirely removed through a dry etching process. As the first base substrate BS is removed, the bottom surfaces of the first connection line 51, the first inorganic layer 61, and the first organic layer 63 may be exposed. The first sensor module 1741 may be inverted. For example, the strain sensor 1740 may be inverted so that the first cover substrate CB1 is arranged at the bottom and the first connection line 51 is arranged at the top.

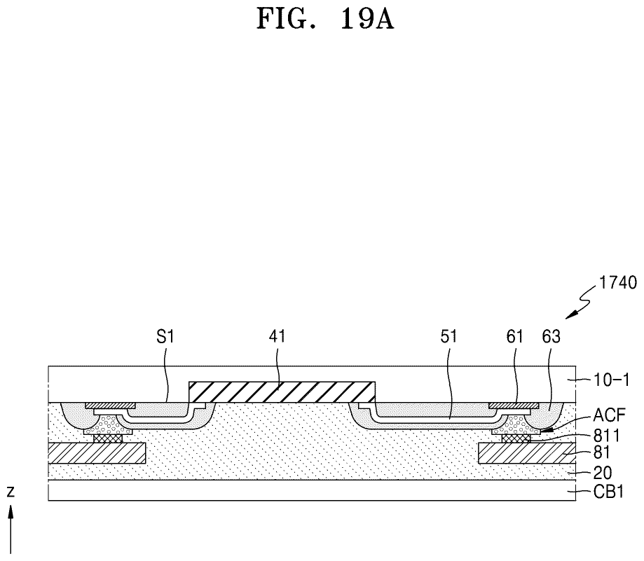

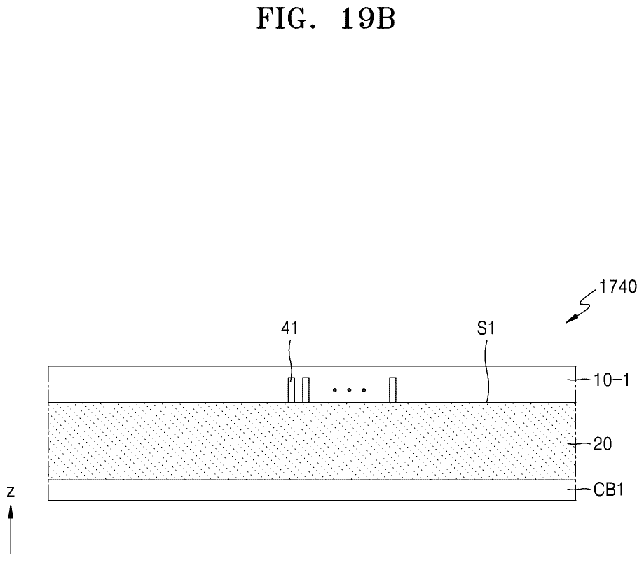

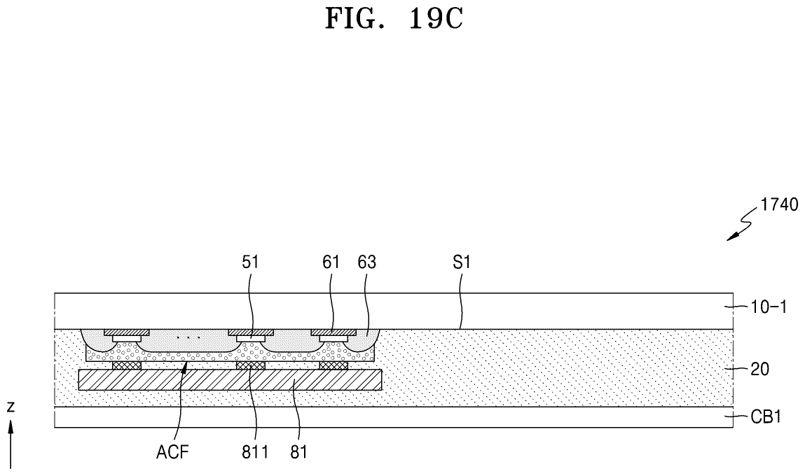

Referring to FIGS. 15 and 19A-19C, operation S211 of manufacturing the first sensor module 1741 (refer to FIG. 10A) may include operation S2116 of arranging the first sensor line 41 to be in contact with the first connection line 51.

One side of the first connection line 51 and the other side of the first connection line 51 may each be in contact with the first sensor line 41. The first sensor line 41 may be in contact with the first elastomer layer 20. The first-1 support layer 10-1 may be arranged on the first elastomer layer 20. The first-1 support layer 10-1 may cover the first sensor line 41. The first-1 support layer 10-1 may cover the first connection line 51.

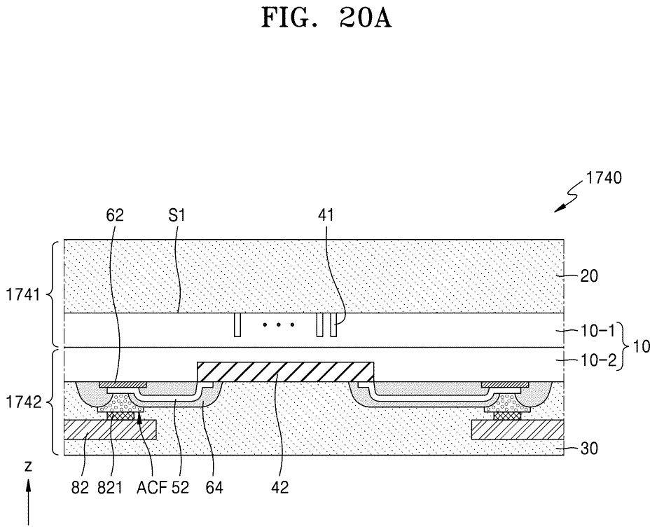

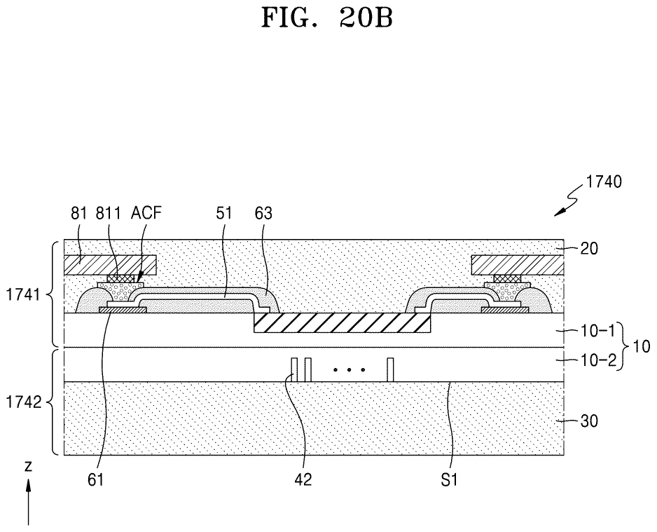

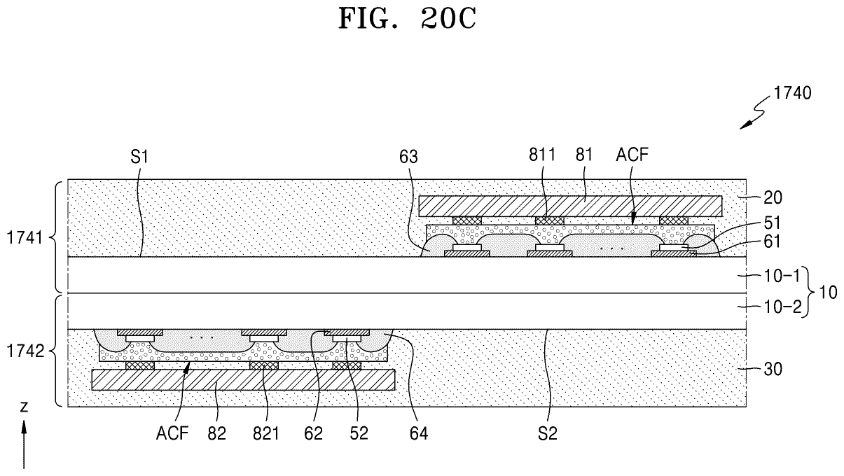

Referring to FIGS. 14 and 20A-20C, operation S21 of manufacturing the strain sensor 1740 may include operation S212 of manufacturing the second sensor module 1742 and operation S213 of bonding the first sensor module 1741 to the second sensor module 1742.

In operation S212 of manufacturing the second sensor module 1742, the second sensor module 1742 may include the second connection line 52, the second circuit board 82 electrically connected to the second connection line 52, and the second sensor line 42 electrically connected to the second connection line 52 and spaced (e.g., spaced apart) from the second circuit board 82. Operation S212 of manufacturing the second sensor module 1742 is substantially the same as operation S211 of manufacturing the first sensor module 1741 described with reference to FIGS. 15-19C, and thus a detailed description thereof is omitted.

In operation S213 of bonding the first sensor module 1741 to the second sensor module 1742, the first sensor line 41 and the second sensor line 42 may cross each other. In operation S213 of bonding the first sensor module 1741 to the second sensor module 1742, the first sensor line 41 and the second sensor line 42 may be arranged to face each other. In operation S213 of bonding the first sensor module 1741 to the second sensor module 1742, the first circuit board 81 and the second circuit board 82 may be arranged to face directions away from each other. In operation S213 of bonding the first sensor module 1741 to the second sensor module 1742, as described above with reference to FIGS. 8A and 8B, the adhesive AD (refer to FIG. 8A) may be arranged between the strain sensor 1740 and the display device 1.

FIG. 21A is a schematic perspective view of the electronic device 1000 including the display device 1 according to one or more embodiments of the disclosure, and FIG. 21B is a schematic block diagram of the electronic device 1000 including the display device 1 according to one or more embodiments of the disclosure.

Referring to FIG. 21A, the electronic device 1000 may freely be deformed three-dimensionally and provide a three-dimensional image surface through the display area DA. The electronic device 1000 being freely deformed three-dimensionally is distinguished from an operation of an electronic device having a rollable display device, such as a case in which the entire display area is recognized by a user while a portion of a rolled-up display area is recognized by the user and then another portion of the rolled-up display area is unfolded (or a case in which only a portion of the display area is recognized while the entire portion of the unfolded display area is recognized to the user and then the display area is rolled up). The electronic device 1000 according to one or more embodiments of the present disclosure may exhibit deformation such that the area of the entire display area DA increases or decreases again while the electronic device 1000 is deformed in an x direction, a y direction, and/or a z direction.

Referring to FIG. 21B, the electronic device 1000 may include the processor 1100, a memory 1200, an input module 1300, a display module 1400, a power module 1500, a built-in module 1600, and an exterior module 1700. According to one or more embodiments, the electronic device 1000 may have at least one of the components described above omitted, or one or more other components may be added. According to one or more embodiments, some of the components described above (for example, the built-in module 1600) may be integrated into another component (for example, the display module 1400).

The processor 1100 may execute software to control at least one other component (e.g., a hardware or software component) of the electronic device 1000 connected to the processor 1100 and may perform various data processing or calculations. According to one or more embodiments, as at least a part of data processing or calculation, the processor 1100 may store commands or data received from another component (e.g., the input module 1300, a sensor module 1610, or a communication module 1730) in volatile memory 1210, process commands or data stored in the volatile memory 1210, and store resulting data in non-volatile memory 1220.

The processor 1100 may include a main processor 1110 and an auxiliary processor 1120. The main processor 1110 may include at least one of a central processing unit (CPU) 1111 and an application processor (AP). The main processor 1110 may further include at least one of a graphics processing unit (GPU) 1112, a communication processor (CP), and an image signal processor (ISP). The main processor 1110 may also further include a neural processing unit (NPU) 1113. An NPU is a processor specialized in processing of artificial intelligence models, and the artificial intelligence models may be created through machine learning. An artificial intelligence model may include a plurality of artificial neural network layers. An artificial neural network may be one of a deep neural network (DNN), a convolutional neural network (CNN), a recurrent neural network (RNN), a restricted Boltzmann machine (RBM), a deep belief network (DBN), a bidirectional recurrent deep neural network (BRDNN), a deep Q-network, or a combination of two or more of the above, but is not limited to the examples described above. An artificial intelligence model may additionally or alternatively include a software structure in addition to a hardware structure. At least two of the processing units and processors described above may be implemented as a single integrated configuration (for example, a single chip) or may each be implemented as an independent configuration (for example, multiple chips).

The auxiliary processor 1120 may include a controller 1121. The controller 1121 may include an interface conversion circuit and a timing control circuit. The controller 1121 may receive an image signal from the main processor 1110 and convert a data format of the image signal to match the interface specifications with the display module 1400 to output the image data. The controller 1121 may output various types of control signals necessary for driving the display module 1400.

The auxiliary processor 1120 may further include data processing circuits such as a data conversion circuit 1122, a gamma correction circuit 1123, and a rendering circuit 1124. The data conversion circuit 1122 may receive image data from the controller 1121 and compensate for the image data so that an image is displayed at a desired brightness according to the characteristics of the electronic device 1000 or the user's setting or convert the image data for reduction in power consumption or compensation for afterimages. The gamma correction circuit 1123 may convert image data or a gamma reference voltage so that an image displayed on the electronic device 1000 has a desired gamma characteristic. The rendering circuit 1124 may receive image data from the controller 1121 and render the image data by considering pixel arrangements of the display device 1 applied to the electronic device 1000. At least one of the data conversion circuit 1122, the gamma correction circuit 1123, and the rendering circuit 1124 may be integrated into another component (for example, the main processor 1110 or the controller 1121). In one or more embodiments, the auxiliary processor 1120 may be integrated into a data driver 1430.

The memory 1200 may store various pieces of data used by at least one component (e.g., the processor 1100 or the sensor module 1610) of the electronic device 1000 and input data or output data with respect to commands related thereto. The memory 1200 may include at least one or more of the volatile memory 1210 and the non-volatile memory 1220.

The input module 1300 may receive commands or data to be used in a component of the electronic device 1000 (e.g., the processor 1100, the sensor module 1610, and/or a sound output module 1630), from the outside of the electronic device 1000 (e.g., a user or an external electronic device 2000).

The input module 1300 may include a first input module 1310 to which a command or data is input from the user and a second input module 1320 to which a command or data is input from the external electronic device 2000.

The first input module 1310 may include a microphone, a mouse, a keyboard, and/or a pen (e.g., a passive pen or an active pen). The first input module 1310 may include a mechanical input unit or a touch input unit such as a button, a dome switch, a jog wheel, a jog switch, and/or the like located on a back surface or a side surface of the electronic device 1000. The touch input unit may include a touch screen layer of the display device 1.

The second input module 1320 may be connected to various types of external electronic devices 2000 connected to the electronic device 1000 via a wired or wireless manner. According to one or more embodiments, the second input module 1320 may include a high definition multimedia interface (HDMI), a universal serial bus (USB) interface, a secure digital (SD) card interface, and/or an audio interface. The second input module 1320 may include a connector capable of physically connecting the electronic device 1000 to the external electronic device 2000, for example, an HDMI connector, a USB connector, an SD card connector, and/or an audio connector (e.g., a headphone connector). The electronic device 1000 may perform appropriate control related to the connected external electronic device 2000 in response to the external electronic device 2000 being connected to the second input module 1320.

The display module 1400 visually provides information to the user. The display module 1400 may include the display device 1, a scan driver 1420, and the data driver 1430.

The display device 1 displays (outputs) information processed by the electronic device 1000. The display device 1 may display execution screen information of an application driven by the electronic device 1000 or a user interface (UI) or graphic user interface (GUI) according to the execution screen information.

The scan driver 1420 may be mounted in the display device 1 as a driving chip. Alternatively, the scan driver 1420 may be directly formed in the display device 1. For example, the scan driver 1420 may include an amorphous silicon TFT gate driver circuit (ASG), a low temperature polycrystalline silicon (LTPS) TFT gate driver circuit, or an oxide semiconductor TFT gate driver circuit (OSG) embedded in the display device 1. The scan driver 1420 receives a control signal from the controller 1121 and outputs a scan signal to the display device 1 in response to the control signal.

The display device 1 may further include an emission control driver. The emission control driver outputs an emission control signal to the display device 1 in response to a control signal received from the controller 1121. The emission control driver may be formed separately from the scan driver 1420 or may be integrated into the scan driver 1420.

The data driver 1430 receives a control signal from the controller 1121, converts image data into data voltages in a form of analog voltages in response to the control signal, and then outputs the data voltages to the display device 1.

The data driver 1430 may be integrated with some components of the auxiliary processor 1120. For example, the data driver 1430 may be provided as a timing controller embedded driver integrated circuit (IC) including the controller 1121.

The power module 1500 supplies power to the components of the electronic device 1000. The power module 1500 may include a battery that charges the power voltage. In addition, the power module 1500 may have a connection port, and the connection port may be included in the second input module 1320 to which an external charger that supplies power to charge the battery is connected. Alternatively, the power module 1500 may include a wireless power transmission/reception member to enable wireless charging of the battery. The wireless power transmission/reception member may include a plurality of antenna radiators in a coil shape. The power module 1500 may include a power management integrated circuit (PMIC). The PMIC supplies optimized power to each component of the electronic device 1000.

The electronic device 1000 may further include the built-in module 1600 and the exterior module 1700. The built-in module 1600 may include the sensor module 1610, an antenna module 1620, and the sound output module 1630. The exterior module 1700 may include a camera module 1710, a light module 1720, the communication module 1730, and/or the strain sensor 1740.

The sensor module 1610 may include touch electrodes and a touch sensor driver of a touch screen layer of the display device 1. The sensor module 1610 may sense an input by the user's body and/or an input by a pen and generate an electrical signal or data value corresponding to the input. The sensor module 1610 may include at least one of a fingerprint sensor 1611, an input sensor 1612, or a digitizer 1613.

The fingerprint sensor 1611 may generate a data value corresponding to the fingerprint of the user. The fingerprint sensor 1611 may include a fingerprint sensor in an optical method and/or a capacitive method.

The input sensor 1612 may generate a data value corresponding to coordinate information of input by the user's body or input by a pen. The input sensor 1612 generates an amount of change in capacitance due to an input into a data value. The input sensor 1612 may sense an input by a passive pen and/or transmit/receive data to/from an active pen.

The input sensor 1612 may also measure biological signals, such as blood pressure, moisture, and/or body fat. For example, when the user contacts a part of his/her body to a sensor layer or sensing panel and does not move a certain period of time, the input sensor 1612 may sense a bio-signal based on a change in electric field caused by the body part and output information desired by the user to the display module 1400.

The digitizer 1613 may generate a data value corresponding to coordinate information of an input by a pen. The digitizer 1613 generates an electromagnetic change amount due to an input into a data value. The digitizer 1613 may sense an input by a passive pen or transmit/receive data to/from an active pen.

In one or more embodiments, at least one of the fingerprint sensor 1611, the input sensor 1612, and the digitizer 1613 may be built into the display device 1. For example, at least one of the fingerprint sensor 1611, the input sensor 1612, and the digitizer 1613 may be formed through a process that is continuous with a process of forming pixel circuits and light-emitting diodes of the display device 1. Therefore, the display device 1 may function as one of the input modules 1300 providing an input interface between the electronic device 1000 and the user and at the same time, may function as the display module 1400 providing an output interface between the electronic device 1000 and the user.

In one or more embodiments, at least two of the fingerprint sensor 1611, the input sensor 1612, and the digitizer 1613 may be formed to be integrated into one sensing panel through the same process. In one or more embodiments, the sensing panel may be arranged between the display device 1 and a window arranged on an upper side of the display device 1, but the present disclosure is not limited thereto.

The antenna module 1620 may include one or more antennas for transmitting signals or power to the outside or receiving signals or power from the outside. According to one or more embodiments, the communication module 1730 may transmit a signal to an external electronic device or receive a signal from the external electronic device through an antenna suitable for a communication method. An antenna pattern of the antenna module 1620 may also be integrated into one component of the display module 1400 (e.g., the display device 1) or the input sensor 1612.

The sound output module 1630 is a device for outputting sound signals to the outside of the electronic device 1000, which may output sound data received from the communication module 1730 in a call signal reception mode, call mode, recording mode, voice recognition mode, and/or broadcast reception mode, and/or sound data stored in the memory 1200. The sound output module 1630 may output sound signals related to functions (for example, a call signal reception sound, a message reception sound, or the like) performed by the electronic device 1000. The sound output module 1630 may include a receiver and/or a speaker. At least one of the receiver or the speaker may be a sound generating device which is attached to a lower portion of the display device 1 and vibrates the display device 1 to output sound. The sound generating device may be a piezoelectric element and/or a piezoelectric actuator which contracts and expands according to an electrical signal, or may be an exciter that vibrates the display device 1 by generating a magnetic force using a voice coil.

The camera module 1710 may capture still images and/or videos. According to one or more embodiments, the camera module 1710 may include one or more lenses, image sensors, and/or image signal processors. The camera module 1710 may further include an infrared camera that may measure the presence or absence of the user, the user's position, the line of sight of the user, and/or the like.

The light module 1720 may output a signal to notify the occurrence of an event by using light of a light source or provide light for image acquisition. Here, examples of the occurrences of events may include reception of a message, reception of a call signal, missing a call, a notification, a calendar reminder, reception of an email, and/or notification of battery charge level information. The light module 1720 may include a light-emitting diode and/or xenon lamp. The light module 1720 may emit light of a single color or multiple colors to the front surface or rear surface of the electronic device 1000. The light module 1720 may operate in conjunction with the camera module 1710 or independently.

The communication module 1730 may support establishment of a wired or wireless communication channel between the electronic device 1000 and the external electronic device 2000 and performance of communication through the established communication channel. The communication module 1730 may include one or both of a wireless communication module, such as a cellular communication module, a short-range wireless communication module, or a global navigation satellite system (GNSS) communication module, and a wired communication module, such as a local area network (LAN) communication module or a power line communication module. The communication module 1730 may transmit and receive wireless signals on the Internet by using at least one of Wireless LAN (WLAN), Wireless-Fidelity (Wi-Fi), Wi-Fi Direct, or Digital Living Network Alliance (DLNA) technologies. Also, the communication module 1730 may support short-range communication by using at least one of Bluetooth™, radio frequency identification (RFID), infrared data association (IrDA), ultra wideband (UWB), ZigBee, near-field communication (NFC), Wi-Fi, Wi-Fi Direct, or wireless universal serial bus (USB) technology. The various types of communication module 1730 described above may be implemented as a single chip or as separate chips.

The strain sensor 1740 may include layers, patterns, or lines of which a measurable physical quantity changes according to the stretching of the display device 1. For example, the strain sensor 1740 may include lines of which the resistance and/or capacitance changes due to stretching of a display device 1. In one or more embodiments, the strain sensor 1740 may include an optical layer or optical pattern of which the transmittance and/or reflectance changes due to stretching of the display device 1.

Based on the physical quantity according to the stretching of the display device 1, which is measured by the strain sensor 1740, the electronic device 1000 may improve the image quality of an image implemented by the display device 1 or control the display device 1. A control operation of the display device 1 may include, for example, an operation of displaying an operation image to protect the display device 1, an operation of cutting off a voltage for driving the display device 1, or an operation of stopping a stretching operation of the display device 1.

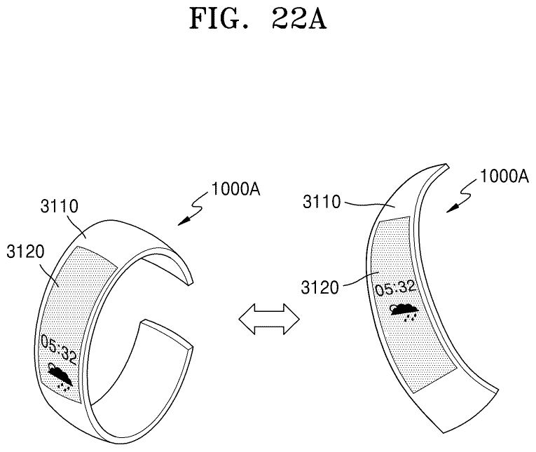

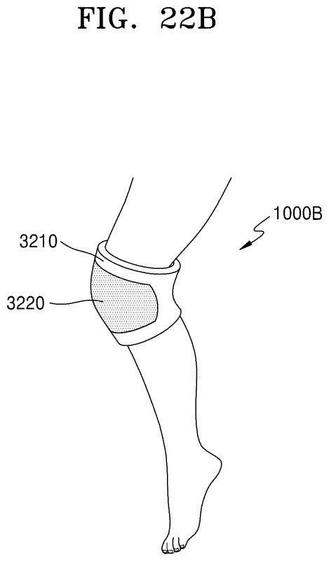

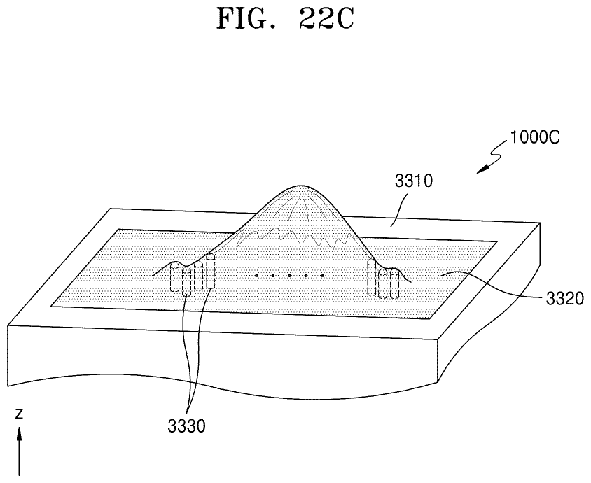

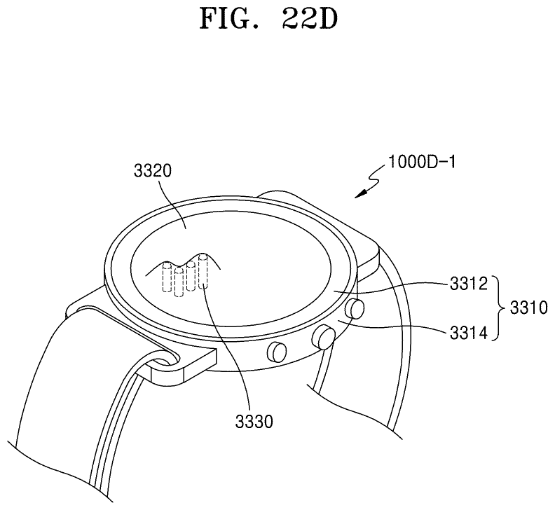

FIGS. 22A-22D are schematic perspective views respectively showing embodiments of an electronic device including a display device according to one or more embodiments of the present disclosure.

Referring to FIG. 22A, a display device according to one or more embodiments may be used in a wearable electronic device 1000A which may be worn on a part of a user's body. The wearable electronic device 1000A may include a body portion 3110 and a display portion 3120 provided in the body portion 3110. A display device according to one or more embodiments of the present disclosure may be used as the display portion 3120 of the wearable electronic device 1000A. As shown in FIG. 22A, the wearable electronic device 1000A may be deformable. In one or more embodiments, the wearable electronic device 1000A may be used as a smart watch or a smartphone depending on the user's choice.

FIG. 22B shows a medical electronic device 1000B. In one or more embodiments, the medical electronic device 1000B may include a body portion 3210 and a light-emitting portion 3220. A display device according to one or more embodiments of the present disclosure may be used as the light-emitting portion 3220 of the medical electronic device 1000B. The light-emitting portion 3220 may emit light of a certain wavelength band (e.g., infrared light, visible light ray, and/or the like) to the body of a patient. In one or more embodiments, the body portion 3210 may include a stretchable fiber material and may have a structure that the light-emitting portion 3220 may be worn on the user's body.

FIG. 22C shows an educational electronic device 1000C. In one or more embodiments, the educational electronic device 1000C may include a display portion 3320 provided in a frame 3310 (3312 and 3314). The display portion 3320 may use a display device according to one or more embodiments of the present disclosure. The display portion 3320 may provide images, such as a sea with waves, a mountain covered with snow, or a volcano with flowing lava, and at this time, the display portion 3320 may extend in a height direction (e.g., a z direction) by reflecting the height of the waves, the mountain, or the volcano. In one or more embodiments, a portion of the display portion 3320 may three-dimensionally show the movement of lava by sequentially changing the height along a direction in which the lava flows. The educational electronic device 1000C may include a plurality of pins (or stroke portions) 3330 arranged on the rear surface of the display portion 3320 so that the display portion 3320 may be stretched in the height direction. While the pins 3330 move along a third direction (e.g., a z direction or a −z direction), an image displayed on the display portion 3320 may be implemented to have a three-dimensional height. FIG. 22C shows the educational electronic device 1000C, but the use is not limited as long as the device provides certain image information.

FIG. 22D shows that a display device is used in a wearable electronic device 1000D-1, such as a smart watch. In one or more embodiments, a display device corresponding to a display portion 3310 of the electronic device 1000D-1 is three-dimensionally stretchable and thus may provide various pieces of haptic information to a user. In one or more embodiments, the electronic device 1000D-1 may provide haptic information, such as braille display for visually impaired or tactile stimulation linked to an image, by using a plurality of pins (or stroke portions) 3330 arranged below the display portion 3310. The display device forming the display portion 3310 is three-dimensionally stretchable and thus may provide the user with the haptic information described above.

The embodiments described with reference to FIGS. 22A-22D describe the electronic devices 1000, 1000B, 1000C, and 1000D-1 in which the display portion is three-dimensionally deformed, but the present disclosure is not limited thereto. As to be described below, a display device according to one or more embodiments of the present disclosure may be used in an electronic device in which a portion capable of displaying images (e.g., a screen) is fixed.

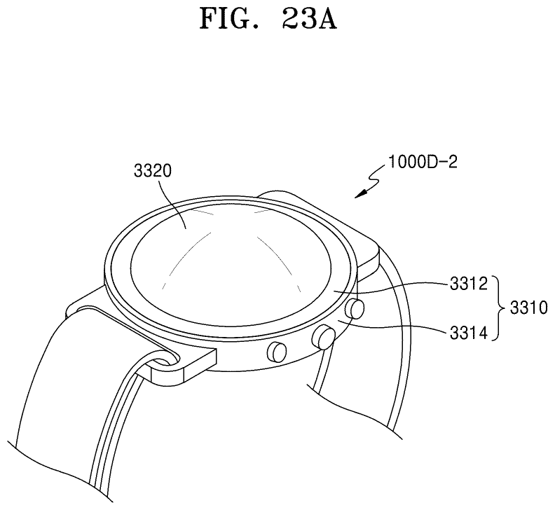

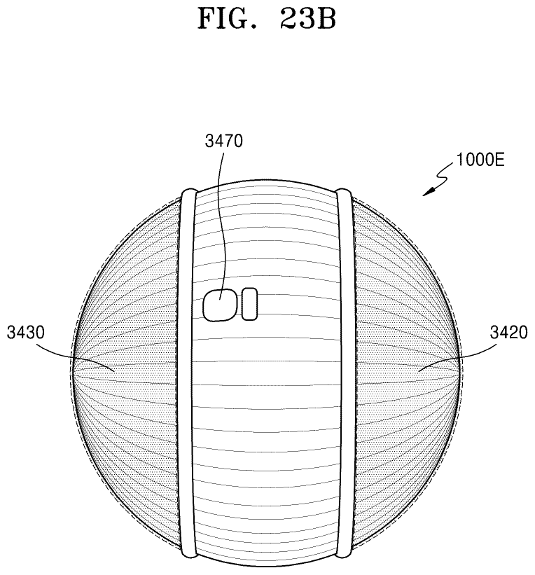

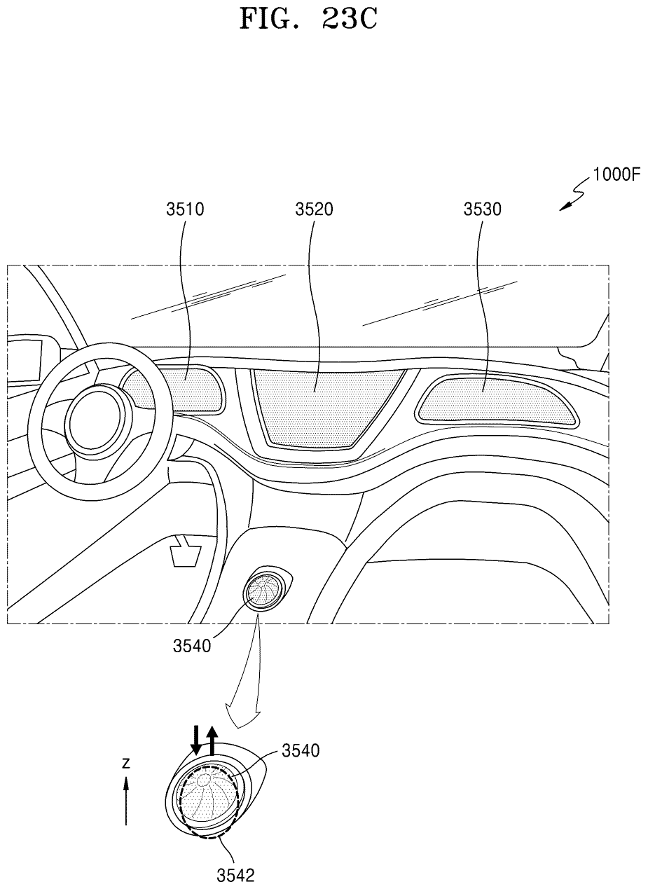

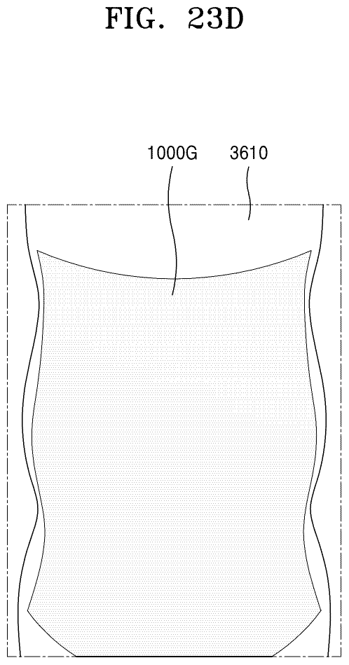

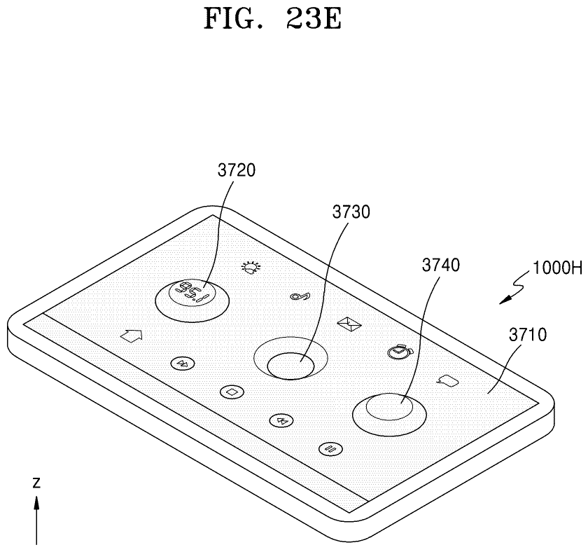

FIGS. 23A-23E are schematic perspective views respectively illustrating electronic devices according to one or more embodiments of the present disclosure.

FIG. 23A shows that a display device is used in a wearable electronic device 1000D-2, such as a smart watch. The electronic device 1000D-2 shown in FIG. 23A includes the display portion 3310, but the display portion 3310 may have a three-dimensional dome shape (or a hemispherical shape). In a process of manufacturing the electronic device 1000D-2, a display device may be assembled into a body frame having a dome shape, and at this time, the display device is three-dimensionally stretchable and thus may be assembled in a stretched state according to the shape of the body frame having the dome shape.

FIG. 23B shows that an electronic device 1000E according to one or more embodiments of the present disclosure includes a robot. The robot may recognize movement or objects by using the camera module 3470 and may display certain images through display portions 3420 and 3430. In one or more embodiments, as described above, because a display device according to one or more embodiments of the present disclosure may be stretched in various directions, the display device may be assembled into a body frame having a hemispherical shape, and accordingly, the robot may include the display portions 3420 and 3430 having hemispherical shapes.

FIG. 23C shows a vehicle display device 1000F as an electronic device according to one or more embodiments of the present disclosure. The vehicle display device 1000F may include a cluster 3510, a center information display (CID) 3520, and/or a co-driver display 3530. Because a display device according to one or more embodiments of the present disclosure may be stretched in various directions, the display device may be used in the cluster 3510, the CID 3520, and/or the co-driver display 3530 regardless of the shape of the internal frame of the vehicle.

FIG. 23C shows that the cluster 3510, the CID 3520, and the co-driver display 3530 are separated from each other, but the present disclosure is not limited thereto. In one or more embodiments, two or more selected from the cluster 3510, the CID 3520, and the co-driver display 3530 may be integrally connected to each other.

In one or more embodiments, the vehicle display device 1000F may include a button 3540 that may display a certain image. Referring to the enlarged view of FIG. 23C, the button 3540 having a hemispherical shape may include an object 3542 that provides the feeling of using while moving in the z direction or the −z direction, and a display device arranged on the object 3542. In one or more embodiments, when the object 3542 has a three-dimensionally rounded surface, the display device may also have a three-dimensionally rounded surface.

FIG. 23D shows that an electronic device according to one or more embodiments of the present disclosure is an advertising or exhibiting electronic device 1000G. In one or more embodiments, the advertising or exhibiting electronic device 1000G may be installed on a fixed structure 3610, such as a wall and/or pillar. When the structure 3610 includes an uneven surface as shown in FIG. 23D, the advertising or exhibiting electronic device 1000G may be arranged along the uneven surface of the structure 3610. In one or more embodiments, the advertising or exhibiting electronic device 1000G may be installed on the structure 3610 by using a heat shrink film and/or the like.

FIG. 23E shows that an electronic device 1000H according to one or more embodiments of the present disclosure includes a controller. The controller may include an image-type button. For example, the controller may include first to third button areas 3720, 3730, and 3740 in which a partial area of a display portion 3710 protrudes in a z direction or a −z direction (or is depressed in the z direction). In one or more embodiments, the first and third button areas 3720 and 3740 may protrude in the z direction, and the second button area 3730 may protrude in the −z direction (or may be depressed in the z direction).

The present disclosure has been described with reference to the embodiments shown in the drawings, but these are merely examples, and those skilled in the art will understand that various modifications and equivalent other embodiments are possible therefrom. Accordingly, the true technical protection scope of the present disclosure should be determined by the technical concept of the attached patent claims and their equivalents.

### EXPLANATION OF REFERENCE NUMERALS

1000: Electronic device
1: Display device
1740: Strain sensor
10: First support layer
20: First elastomer layer
30: Second elastomer layer
40: Sensor line portion
50: Connection line portion
61: First inorganic layer
62: Second inorganic layer
63: First organic layer
64: Second organic layer

What is claimed is:

1. An electronic device including a display area and a non-display area,
wherein the electronic device comprises a display device and a strain sensor attached to the display device, the strain sensor comprising:
a sensor line portion in the display area and comprising a plurality of first sensor lines extending in a first direction and a plurality of second sensor lines extending in a second direction crossing the first direction;
a circuit board portion comprising a first circuit board and a second circuit board in the non-display area, the first circuit board and the second circuit board being spaced from each other;
a connection line portion the non-display area and comprising a plurality of first connection lines electrically connecting the plurality of first sensor lines respectively to the first circuit board, and a plurality of second connection lines electrically connecting the plurality of second sensor lines respectively to the second circuit board; and
a first support layer supporting the sensor line portion, the connection line portion, and the circuit board portion and having a first support surface and a second support surface opposite to the first support surface,
wherein the first circuit board is on the first support surface, and the second circuit board is on the second support surface.

2. The electronic device of claim 1, wherein each of the plurality of first connection lines is on the first support surface, and
wherein each of the plurality of second connection lines is on the second support surface.

3. The electronic device of claim 1, wherein each of the plurality of first sensor lines and the plurality of second sensor lines has a straight-line shape, and
wherein each of the plurality of first connection lines and the plurality of second connection lines has a serpentine shape.

4. The electronic device of claim 1, wherein the strain sensor further comprises:
a plurality of first connection portions electrically connecting the plurality of first connection lines respectively to the first circuit board; and
a plurality of first inorganic layers respectively located between the first support layer and the plurality of first connection lines to overlap the plurality of first connection portions.

5. The electronic device of claim 1, wherein the strain sensor further comprises a plurality of first organic layers on the first support surface to respectively cover the plurality of first connection lines.

6. The electronic device of claim 1, wherein at least two of the plurality of first connection lines have different cross-sectional areas from one another.

7. The electronic device of claim 1, wherein, in a plan view, the first circuit board and the second circuit board overlap each other.

8. The electronic device of claim 1, wherein the second circuit board comprises a second-1 circuit board and a second-2 circuit board, and,
wherein, in a plan view, the second-1 circuit board, the first circuit board, and the second-2 circuit board are sequentially arranged along the first direction.

9. The electronic device of claim 1, wherein the plurality of first sensor lines and the plurality of second sensor lines face each other.

10. The electronic device of claim 1, wherein the first circuit board and the second circuit board face away from each other.

11. The electronic device of claim 1, wherein, in a plan view, the plurality of first sensor lines and the plurality of second sensor lines cross each other.

12. The electronic device of claim 1, wherein, in a cross-sectional view, the plurality of first sensor lines and the plurality of second sensor lines are spaced from each other.

13. A method of manufacturing an electronic device, the method comprising manufacturing a strain sensor and attaching the strain sensor to a display device,
wherein the manufacturing of the strain sensor comprises:
manufacturing a first sensor module;
manufacturing a second sensor module; and
bonding the first sensor module to the second sensor module,
wherein the manufacturing of the first sensor module comprises:
arranging a first base substrate on a first support substrate;
arranging first connection line on the first base substrate;
arranging a first circuit board on the first connection line;
arranging first cover substrate on the first circuit board;
removing the first support substrate and the first base substrate; and
arranging a first sensor line to be in contact with the first connection line.

14. The method of claim 13, wherein, in the manufacturing of the second sensor module, the second sensor module comprises a second connection line, a second circuit board electrically connected to the second connection line, and a second sensor line electrically connected to the second connection line and spaced from the second circuit board.

15. The method of claim 14, wherein, in the bonding of the first sensor module to the second sensor module, the first sensor line and the second sensor line cross each other.

16. The method of claim 14, wherein, in the bonding of the first sensor module to the second sensor module, the first sensor line and the second sensor line face each other.

17. The method of claim 14, wherein, in the bonding of the first sensor module to the second sensor module, the first circuit board and the second circuit board face away from each other.

18. The method of claim 14, wherein each of the first sensor line and the second sensor line has a straight-line shape, and
wherein each of the first connection line and the second connection line has a serpentine shape.

19. The method of claim 14, wherein, in a plan view, the first circuit board and the second circuit board are spaced from each other.

20. The method of claim 14, wherein the second circuit board comprises a second-1 circuit board and a second-2 circuit board, and,
in a plan view, the second-1 circuit board, the first circuit board, and the second-2 circuit board are sequentially arranged along a first direction.
